(19) United States
(12) Patent Application Publication
(10) Pub. No.: US 2026/0182221 A1
(43) Pub. Date: Jun. 25, 2026

(54) ORGANIC LIGHT EMITTING DEVICES AND METHODS OF MANUFACTURING THE SAME

(71) Applicant: TAIZHOU GUANYU TECHNOLOGY CO., LTD., ZHEJIANG PROVINCE (CN)

(72) Inventors: YICHANG WANG, ZHEJIANG PROVINCE (CN); LI-CHEN WEI, TAICHUNG CITY (TW); KUO-CHENG HSU, TAICHUNG CITY (TW)

(21) Appl. No.: 19/372,283

(22) Filed: Oct. 29, 2025

(30) Foreign Application Priority Data
Dec. 19, 2024 (CN) 202411886746.7

(51) Int. Cl. H10K 59/80; H10K 59/12

(52) U.S. Cl. CPC H10K 59/878; H10K 59/1201; H10K 59/80518

(57) ABSTRACT

An organic light-emitting device includes a substrate, a first electrode located on the substrate, an organic light-emitting layer located on the first electrode, and a second electrode located on the organic light-emitting layer, and one of the first electrode and the second electrode including a transparent electrode, wherein one of the first electrode and the second electrode provides a reflectance of 30% or more for light emitted from the organic light-emitting layer, while the other provides a reflectance of 80% or more for the light emitted from the organic light-emitting layer.

### PRIORITY CLAIM AND CROSS-REFERENCE

This application claims the benefit of China patent application No. 202411886746.7, filed on December 19, 2024, the entirety of which are incorporated by reference herein.

### BACKGROUND OF THE DISCLOSURE

### FIELD OF THE DISCLOSURE

The present disclosure relates to an organic light-emitting device, and more particularly to an organic light-emitting device including an organic light-emitting diode (OLED) structure.

### DESCRIPTION OF THE PRIOR ART

Currently, a fine metal mask (FMM) is commonly used for a coating step of a light-emitting layer of an organic light-emitting device, or white light in combination with a color film is used for the process. The pixel fineness or resolution produced by the above process is rather poor.

### SUMMARY OF THE DISCLOSURE

In the present disclosure, an organic light-emitting device includes a substrate, a first electrode located on the substrate, an organic light-emitting layer located on the first electrode, and a second electrode located on the organic light-emitting layer, and one of the first electrode and the second electrode comprising a transparent electrode. Wherein one of the first electrode and the second electrode provides a reflectance of 30% or more for light emitted from the organic light-emitting layer, while the other provides a reflectance of 80% or more for the light emitted from the organic light-emitting layer.

In the present disclosure, a manufacturing method of an organic light-emitting device includes: providing a substrate; disposing a first electrode on the substrate; forming an organic light-emitting layer on the first electrode; and disposing a second electrode on the organic light-emitting layer, one of the first electrode and the second electrode comprising a transparent electrode, wherein a reflectance provided by one of the first electrode and the second electrode when disposed to reflect light emitted from the organic light-emitting layer is 30% or more, and a reflectance provided by the other of the first electrode and the second electrode when disposed to reflect the light emitted from the organic light-emitting layer is 80% or more.

In some embodiments, the first electrode is the transparent electrode, and the organic light-emitting device further comprises a first reflector located on the transparent electrode, and the first reflector located between the substrate and the transparent electrode, or the first reflector located between the transparent electrode and the organic light-emitting layer, wherein the first reflector is disposed to provide a reflection for the light emitted from the organic light-emitting layer.

In some embodiments, the second electrode comprises another transparent electrode, and the organic light-emitting device further comprises a second reflector located on the second electrode, and the second electrode located between the second reflector and the organic light-emitting layer, or the second reflector located between the second electrode and the organic light-emitting layer, wherein a reflectance provided by the first reflector when disposed to reflect the light emitted from the organic light-emitting layer is different from a reflectance provided by the second reflector when disposed to reflect the light emitted from the organic light-emitting layer.

In some embodiments, a thickness of the first reflector is different from a thickness of the second reflector.

In some embodiments, the organic light-emitting layer is a first organic light-emitting layer, and the organic light-emitting device further comprises a third electrode located on the substrate, wherein the third electrode and the first electrode include a same transparent conductive material; a second organic light-emitting layer located on the third electrode; a third reflector located on the third electrode, and the third reflector located between the substrate and the third electrode, or the third reflector located between the third electrode and the second organic light-emitting layer; a fourth electrode, including a same transparent conductive material as the second electrode, located on the second organic light-emitting layer; and a fourth reflector located on the fourth electrode, and the fourth electrode located between the fourth reflector and the second organic light-emitting layer, or the fourth reflector located between the fourth electrode and the second organic light-emitting layer, wherein a reflectance provided by the fourth reflector when disposed to reflect light emitted from the second organic light-emitting layer is different from a reflectance provided by the third reflector when disposed to reflect the light emitted from the second organic light-emitting layer.

In some embodiments, a thickness of the first electrode is different from a thickness of the third electrode.

In some embodiments, a thickness of the second reflector is different from a thickness of the fourth reflector.

In some embodiments, the first electrode is a first metal electrode, the organic light-emitting layer is a first organic light-emitting layer, the second electrode is the transparent electrode, and the organic light-emitting device further comprises a first reflector located on the second electrode, and the second electrode located between the first reflector and the first organic light-emitting layer, or the first reflector located between the second electrode and the first organic light-emitting layer; a third electrode located on the substrate, wherein the third electrode is a second metal electrode; a second organic light-emitting layer located on the third electrode; a fourth electrode, which is another transparent electrode, located on the second organic light-emitting layer; and a second reflector located on the fourth electrode, and the fourth electrode located between the second reflector and the second organic light-emitting layer, or the second reflector located between the fourth electrode and the second organic light-emitting layer.

In some embodiments, a reflectance provided by the first reflector when disposed to reflect light emitted from the first organic light-emitting layer is different from a reflectance provided by the second reflector when disposed to reflect light emitted from the second organic light-emitting layer.

In some embodiments, the first electrode is the transparent electrode, the second electrode is a first metal electrode, the organic light-emitting layer is a first organic light-emitting layer, and the organic light-emitting device further comprises a reflector located between the first electrode and the substrate; a third electrode, which is another transparent electrode, located on the substrate; a second organic light-emitting layer located on the third electrode, and the reflector extending between the third electrode and the substrate, or extending between the third electrode and the second organic light-emitting layer; and a fourth electrode located on the second organic light-emitting layer, the fourth electrode being a second metal electrode, wherein a reflectance provided by the reflector when disposed to reflect light emitted from the second organic light-emitting layer is different from a reflectance provided by the reflector when disposed to reflect light emitted from the first organic light-emitting layer.

In some embodiments, a thickness of the second electrode is different from a thickness of the fourth electrode.

In some embodiments, the manufacturing method further comprises: using a transparent conductive material to form the first electrode; and disposing a first reflector on a surface of the first electrode, wherein the first reflector is located between the substrate and the first electrode, or the first reflector is located between the first electrode and the organic light-emitting layer.

In some embodiments of the manufacturing method, another transparent conductive material is used to form the second electrode, and the manufacturing method further comprises: disposing a second reflector on the second electrode, and the second electrode located between the second reflector and the organic light-emitting layer, or the second reflector located between the second electrode and the organic light-emitting layer, wherein a reflectance provided by the first reflector when disposed to reflect the light emitted from the organic light-emitting layer is different from a reflectance provided by the second reflector when disposed to reflect the light emitted from the organic light-emitting layer.

In some embodiments of the manufacturing method, further comprising using the transparent conductive material to form a third electrode on the substrate, wherein the third electrode and the first electrode are disposed to be separated from each other; disposing a third reflector on a surface of the third electrode; forming a second organic light-emitting layer on the third electrode, wherein the third reflector is located between the substrate and the third electrode, or the third reflector is located between the third electrode and the second organic light-emitting layer; forming a fourth electrode on the second organic light-emitting layer; and forming a fourth reflector on the fourth electrode, and the fourth electrode located between the fourth reflector and the second organic light-emitting layer, or the fourth reflector located between the fourth electrode and the second organic light-emitting layer, wherein a reflectance provided by the fourth reflector when disposed to reflect light emitted from the second organic light-emitting layer is different from a reflectance provided by the second reflector when disposed to reflect the light emitted from the second organic light-emitting layer.

In some embodiments, a thickness of the fourth electrode is different from a thickness of the second electrode.

In some embodiments, the manufacturing method comprises: using a transparent conductive material to make one of the first electrode and the second electrode, so that a reflectance of the one of the first electrode and the second electrode to the light emitted from the organic light-emitting layer is 30% or more; using a metal material to make the other of the first electrode and the second electrode, so that a reflectance of the other of the first electrode and the second electrode to the light emitted from the organic light-emitting layer is 80% or more; and disposing a reflector on one of the first electrode and the second electrode made of the transparent conductive material, so that a reflectance provided by the reflector when disposed to reflect the light emitted from the organic light-emitting layer is 30% or more.

### BRIEF DESCRIPTION OF THE DRAWINGS

FIG. 1 is a top view illustrating an intermediate product of an organic light-emitting device.

FIG. 2A is a cross-sectional view illustrating an organic light-emitting device.

FIG. 2B is a cross-sectional view illustrating an organic light-emitting component.

FIG. 2C is a cross-sectional view illustrating an organic light-emitting device.

FIG. 2D is a cross-sectional view illustrating an organic light-emitting component.

FIG. 2E is a cross-sectional view illustrating an organic light-emitting device.

FIG. 2F is a cross-sectional view illustrating an organic light-emitting device.

FIG. 2G is a cross-sectional view illustrating an organic light-emitting device.

FIG. 2H is a cross-sectional view illustrating an organic light-emitting device.

FIG. 3A to FIG. 3F depict a manufacturing method of an organic light-emitting device according to some embodiments.

FIG. 4 is a top view illustrating an intermediate product of an organic light-emitting device.

FIG. 5A is a cross-sectional view illustrating an organic light-emitting device.

FIG. 5B is a cross-sectional view illustrating an organic light-emitting device.

FIG. 5C is a cross-sectional view illustrating an organic light-emitting device.

FIG. 5D is a cross-sectional view illustrating an organic light-emitting device.

FIG. 5E is a cross-sectional view illustrating an organic light-emitting device.

FIG. 5F is a cross-sectional view illustrating an organic light-emitting component.

FIG. 5G is a cross-sectional view illustrating an organic light-emitting component.

FIG. 5H is a cross-sectional view illustrating an organic light-emitting component.

FIG. 6A to FIG. 6G depict a manufacturing method of an organic light-emitting device according to some embodiments.

### DETAILED DESCRIPTION OF THE EMBODIMENTS

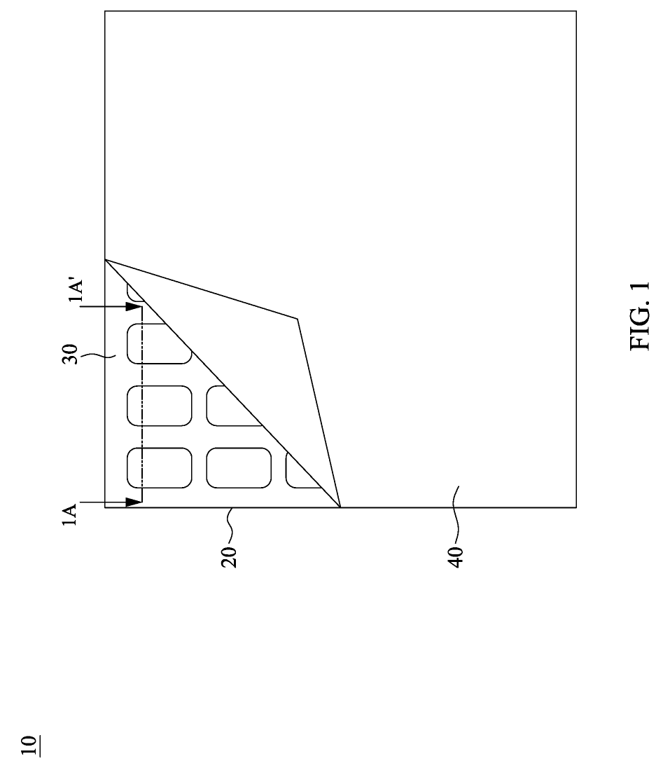

FIG. 1 is a top view illustrating an intermediate product of an organic light-emitting device 10. The organic light-emitting device 10 includes a light-emitting layer 20 and a cover layer 40 located above the light-emitting layer 20. For the light-emitting layer 20, a spacer structure 30 may be designed to provide an array of recesses for accommodating the array of light-emitting pixels. In some embodiments, the spacer structure 30 may include bumps 310. In some embodiments, the spacer structure 30 may include photosensitive material.

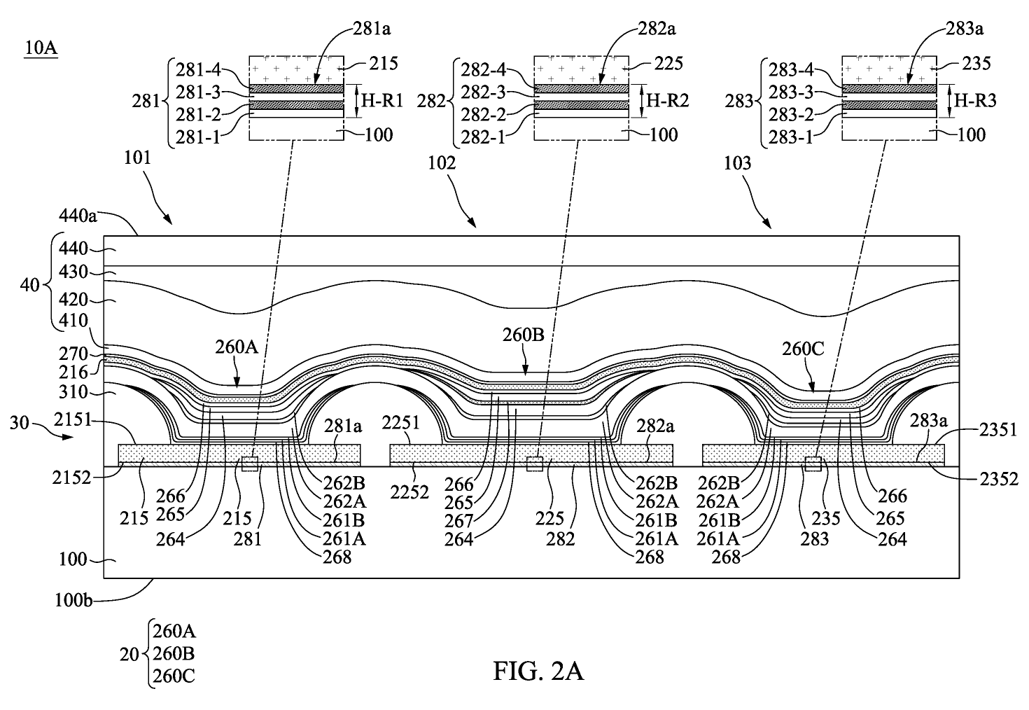

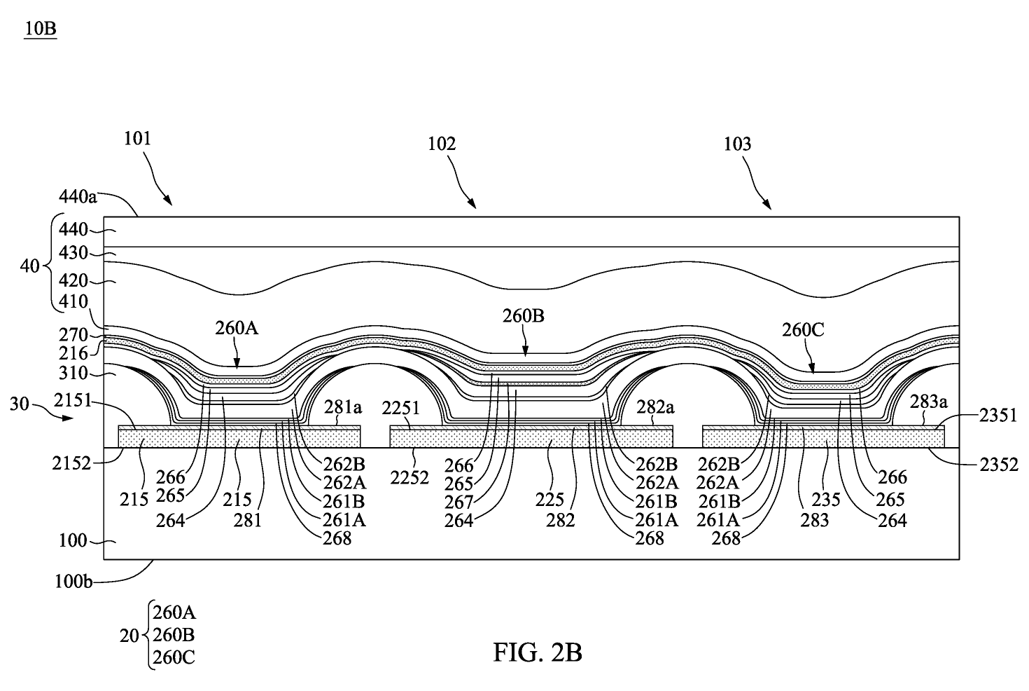

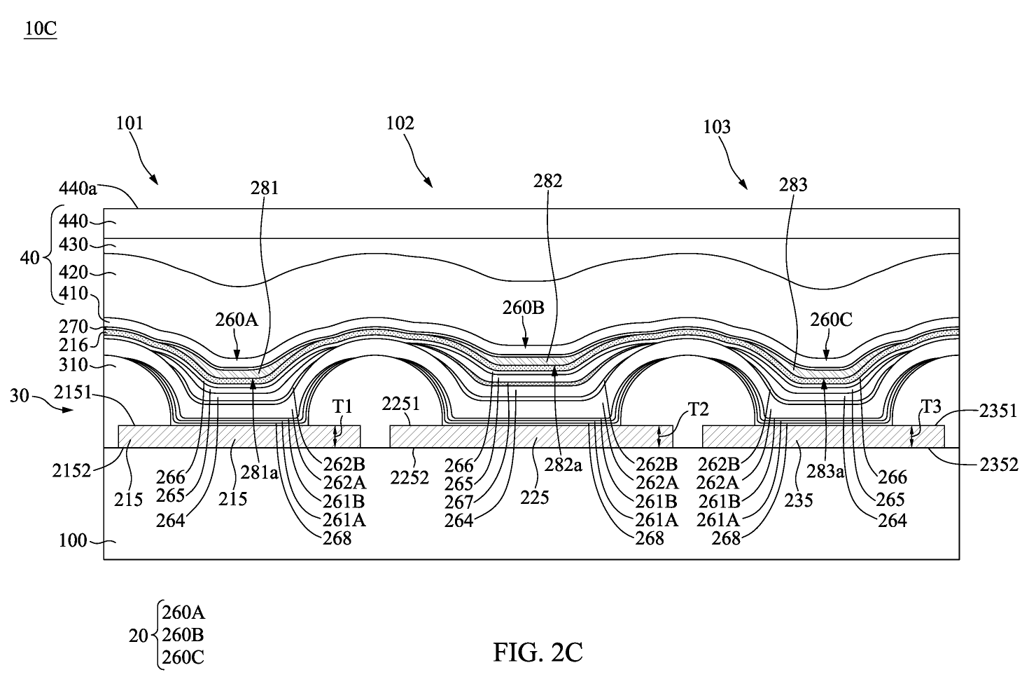

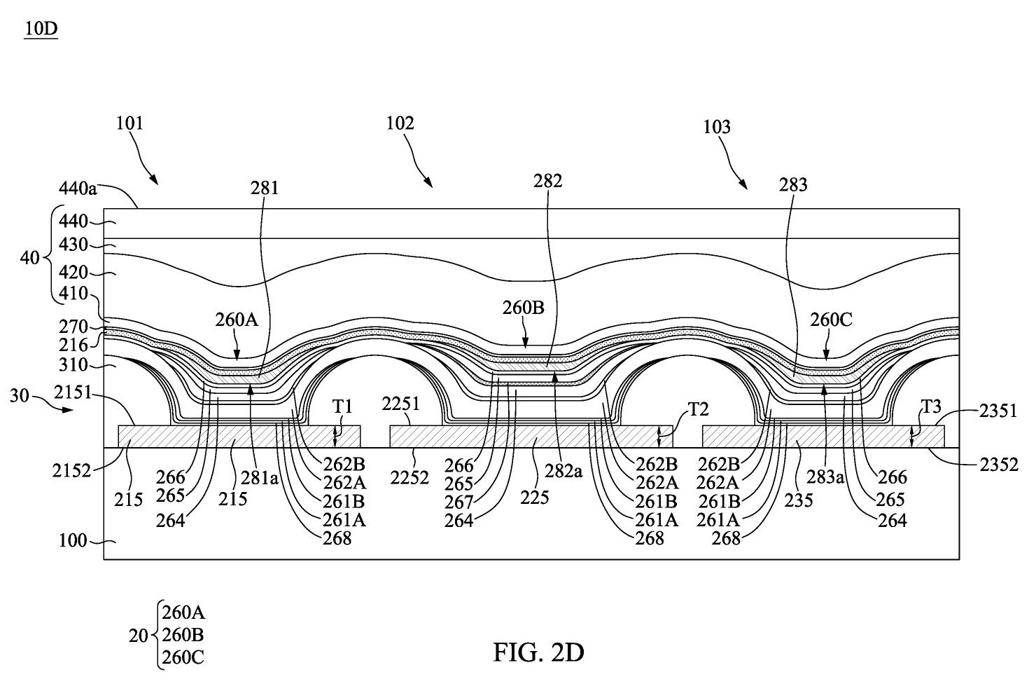

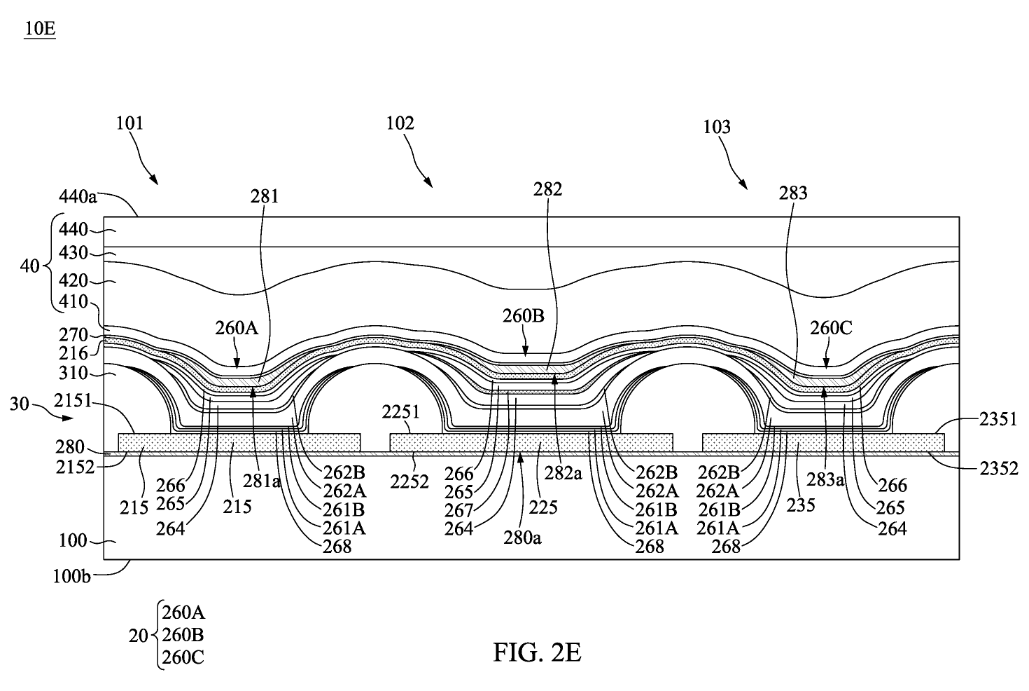

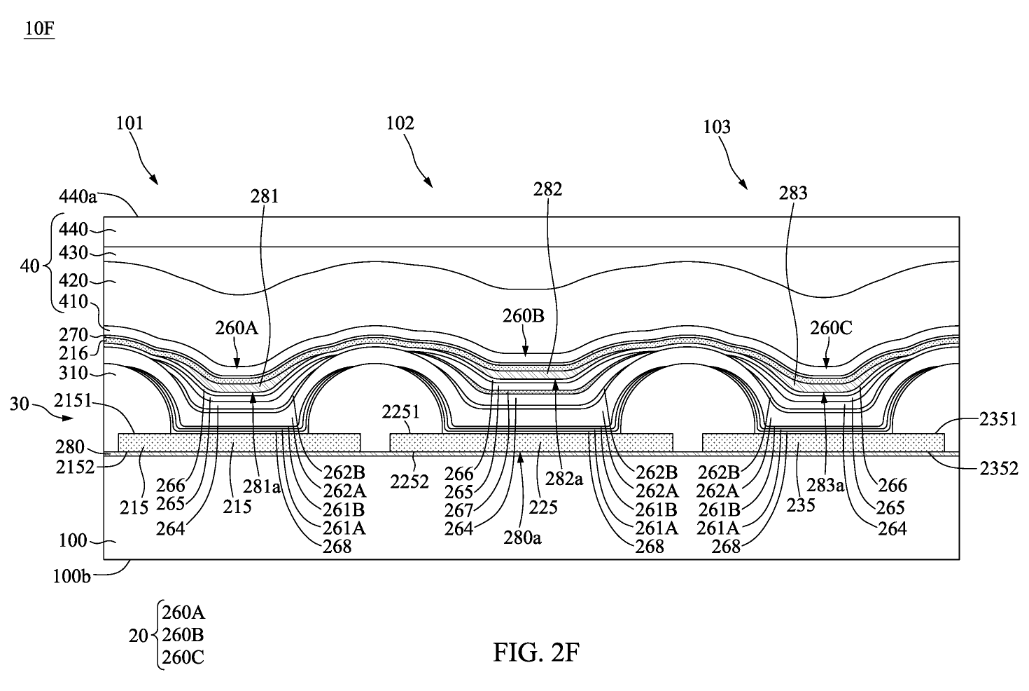

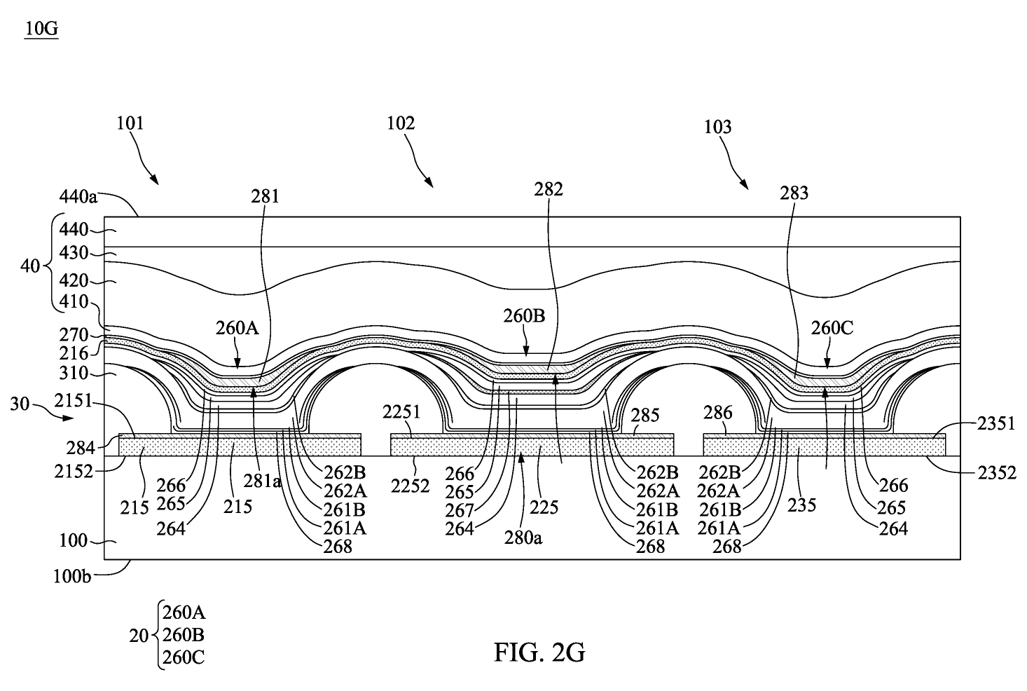

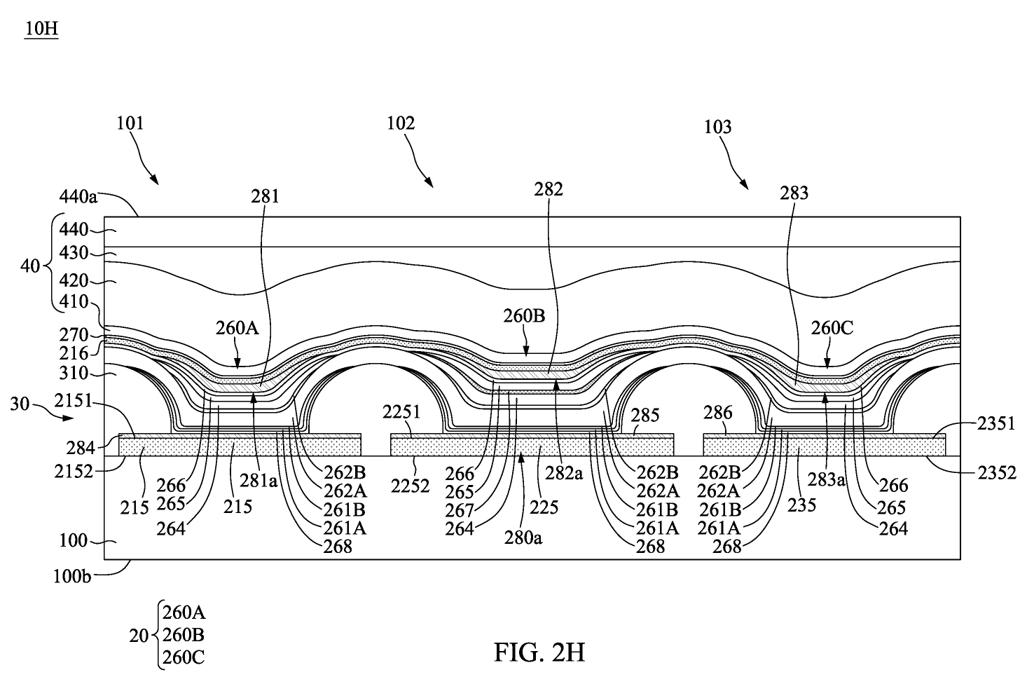

FIG. 2A is a cross-sectional view illustrating an organic light-emitting device 10A. In some embodiments, FIG. 2A is a cross-sectional view along a line 1A-1A’ in FIG. 1. In some embodiments, FIG. 2A is a cross-sectional view along the line 1A-1A’ in FIG. 1 and only illustrates a light-emitting region. The spacer structure 30 comprise several bumps 310 to define a light-emitting pixel pattern. The recess is located between two adjacent bumps 310 and provide a space for accommodating the light-emitting pixels. It should be understood by those skilled in the art that, when viewed from the cross-sectional view of FIG. 2A, the bumps 310 are shown as disconnected, but when viewed from the top view of FIG. 1, they may be connected to each other via other parts of the spacer structure 30.

As shown in FIG. 2A, in some embodiments, the organic light-emitting device 10A is, for example, a light-emitting device including an organic light-emitting diode (OLED) structure. In some embodiments, the organic light-emitting device 10 includes a plurality of organic light-emitting units (also referred to as light-emitting pixels), for example, including at least an organic light-emitting unit 101 (also referred to as a first organic light-emitting unit), an organic light-emitting unit 102 (also referred to as a second organic light-emitting unit), and an organic light-emitting unit 103 (also referred to as a third organic light-emitting unit). In some embodiments, the organic light-emitting units 101, 102, and 103 are located between the bumps 310 and above a substrate 100. The organic light-emitting units 101, 102, and 103 can emit light of the same wavelength or different wavelengths.

In some embodiments, the organic light-emitting device 10 includes the substrate 100, an electrode 215, an electrode 225, an electrode 235, an electrode 216, the light-emitting layer 20, an inorganic barrier layer 268, an inorganic barrier layer 270, a reflector 281, a reflector 282, a reflector 283, the spacer structure 30, and a cover layer 40.

In some embodiments, the substrate 100 may include a transistor array, which is configured to correspond to the light-emitting pixels in the light-emitting layer 20. The substrate 100 may include several capacitors. In some embodiments, more than one transistor is configured to form a circuit with a capacitor and a light-emitting pixel. In some embodiments, the substrate 100 may include glass.

In some embodiments, the electrodes 215, 225, and 235 are located on the substrate 100. In some embodiments, the electrodes 215, 225, and 235 are anodes. The electrodes 215, 225, and 235 may also be referred to as bottom electrodes of the organic light-emitting device 10. In some embodiments, the electrodes 215, 225, and 235 include metallic materials such as Ag, Al, Mg, Au, AlCu alloy, AgMo alloy, etc. In some embodiments, the electrodes 215, 225, and 235 include indium tin oxide (ITO), indium zinc oxide (IZO), or other suitable materials.

In some embodiments, the light-emitting layer 20 includes an organic light-emitting layer 260A (also known as a first organic light-emitting layer), an organic light-emitting layer 260B (also known as a second organic light-emitting layer), and an organic light-emitting layer 260C (also known as a third organic light-emitting layer). In some embodiments, the organic light-emitting layer 260A is located on the electrode 215, the organic light-emitting layer 260B is located on the electrode 225, and the organic light-emitting layer 260C is located on the electrode 235. In some embodiments, thicknesses of the organic light-emitting layers 260A, 260B, and 260C are different from each other. In some embodiments, the thickness of the organic light-emitting layer 260B is greater than the thickness of the organic light-emitting layer 260A, and the thickness of the organic light-emitting layer 260A is greater than the thickness of the organic light-emitting layer 260C.

In some embodiments, the organic light-emitting layers 260A, 260B, and 260C emit light of the same or different colors. In some embodiments, a light-emitting wavelength of the organic light-emitting layer 260B is greater than a light-emitting wavelength of the organic light-emitting layer 260A, and a light-emitting wavelength of the organic light-emitting layer 260A is greater than a light-emitting wavelength of the organic light-emitting layer 260C. In some embodiments, the organic light-emitting layer 260A emits green light, the organic light-emitting layer 260B emits red light, and the organic light-emitting layer 260C emits blue light.

In some embodiments, organic material layers of the organic light-emitting layers 260A, 260B, and 260C include organic materials, which may be placed in any of the organic material layers of the organic light-emitting layers 260A, 260B, and 260C according to different implementations. In some embodiments, an absorptivity of the organic material for a specific wavelength is greater than or equal to 50%, or greater than or equal to 60%, or greater than or equal to 70%, or greater than or equal to 80%, or greater than or equal to 90%. In some embodiments, the absorptivity of the organic material for the specific wavelength is greater than or equal to 95%. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

As shown in FIG. 2A, in some embodiments, the organic light-emitting unit 101 includes the electrode 215, the organic light-emitting layer 260A, and the electrode 216. The electrode 216 may also be referred to as a top electrode of the organic light-emitting device. In some embodiments, the organic light-emitting layer 260A includes a plurality of organic material layers, such as a hole injection layer (HIL) 261A, a hole injection layer (HIL) 261B, a hole transport layer (HTL) 262A, a hole transport layer (HTL) 262B, an organic emission layer (EM) 264, an electron transport layer (ETL) 265, and an electron injection layer (EIL) 266. In some embodiments, the electrode 216 is located above the organic light-emitting layer 260A.

As shown in FIG. 2A, in some embodiments, the organic light-emitting unit 102 includes the electrode 225, the organic light-emitting layer 260B, and the electrode 216. In some embodiments, the organic light-emitting layer 260B includes a plurality of organic material layers, such as the hole injection layer (HIL) 261A, the hole injection layer (HIL) 261B, the hole transport layer (HTL) 262A, the hole transport layer (HTL) 262B, the organic emission layer (EM) 264, a hole blocking layer (HBL) 267, the electron transport layer (ETL) 265, and the electron injection layer (EIL) 266. In some embodiments, the electrode 216 is located above the organic light-emitting layer 260B.

As shown in FIG. 2A, in some embodiments, the organic light-emitting unit 103 includes the electrode 235, the organic light-emitting layer 260C, and the electrode 216. In some embodiments, the organic light-emitting layer 260C include a plurality of organic material layers, such as the hole injection layer (HIL) 261A, the hole injection layer (HIL) 261B, the hole transport layer (HTL) 262A, the hole transport layer (HTL) 262B, the organic emission layer (EM) 264, the electron transport layer (ETL) 265, and the electron injection layer (EIL) 266. In some embodiments, the electrode 216 is located above the organic light-emitting layer 260C.

In some embodiments, the organic light-emitting layers 260A, 260B, and 260C may have the same or different thicknesses.

In some embodiments, the electrode 216 is in contact with the organic light-emitting layers 260A, 260B, and 260C. The electrode 216 may be a continuous film as shown in FIG. 2A and is located above the organic light-emitting layers 260A, 260B, and 260C and the bump 310. In some embodiments, the electrode 216 may further be located on the spacer structure 30. In some embodiments, the electrode 216 is a common electrode for all light-emitting pixels in the light-emitting layer 20. In some embodiments, the electrode 216 includes metallic materials such as Ag, Al, Mg, Au, AlCu alloy, AgMo alloy, etc. In some embodiments, the electrode 216 includes, for example, ITO, IZO, or other suitable materials. In other words, the electrode 216 is the common electrode for several organic light-emitting units. In some embodiments, the electrode 216 is the common electrode for all organic light-emitting units in the organic light-emitting device 10A.

In some embodiments shown in FIG. 2A, the electrode 216 includes a conductive material having high reflectance, such as a reflectance of 80% or more for light emitted from the organic light-emitting layers 260A, 260B, and 260C, for example, 80% or more, 85% or more, 90% or more, or 95% or more. In some embodiments, the electrodes 215, 225, and 235 are transparent electrodes, for example, including ITO, IZO, or other suitable materials, and reflectors are disposed on surfaces of the electrodes 215, 225, and 235 to enhance a light reflectance on sides of the electrodes 215, 225, and 235, achieving a resonant cavity effect. In some embodiments, the reflectors 281, 282, and 283 are respectively located between the substrate 100 and the electrodes 215, 225, and 235.

Specifically, in some embodiments, a surface 2151 of the electrode 215 faces the electrode 216, and a surface 2152 of the electrode 215 relative to the surface 2151 faces the substrate 100 and is in contact with the reflector 281. In some embodiments, the reflector 281 includes a surface 281a, and the surface 281a faces the organic light-emitting layer 260A and is in contact with the electrode 215. Similarly, in some embodiments, a surface 2251 of the electrode 225 faces the electrode 216, and a surface 2252 of the electrode 225 relative to the surface 2251 faces the substrate 100 and is in contact with the reflector 282. In some embodiments, the reflector 282 includes a surface 282a, and the surface 282a faces the organic light-emitting layer 260B and is in contact with the electrode 225. Similarly, in some embodiments, a surface 2351 of the electrode 235 faces the electrode 216, and a surface 2352 of the electrode 235 relative to the surface 2351 faces the substrate 100 and is in contact with the reflector 283. In some embodiments, the reflector 283 includes a surface 283a, and the surface 283a faces the organic light-emitting layer 260C and is in contact with the electrode 235.

In some embodiments where the electrode 216 is a high-reflectance electrode and the electrodes 215, 225, and 235 are transparent electrodes, the reflectors 281, 282, and 283 are disposed to enhance the reflectance of light emitted from the organic light-emitting layers 260A, 260B, and 260C, where a light-emitting surface of the organic light-emitting device 10A is a surface 100b of the substrate 100. In some embodiments, the reflectors 281, 282, and 283 each include silver, a distributed Bragg reflector (DBR), or other suitable reflective materials. In embodiments where DBR is used as the reflector, it is formed by alternately stacking multiple layers of dielectric materials having different refractive indices, and a difference in refractive indices of different dielectric materials may generate reflection within the DBR. In some embodiments, the reflector may generate reflection on a contact surface with the transparent electrode.

Regardless of whether the reflection is generated inside the reflector (e.g., DBR) in some embodiments, or the reflection is generated on a surface of the reflector in some other embodiments, or the reflection is generated on a contact surface between the reflector and the transparent electrode in some other embodiments, or the reflection is generated inside the transparent electrode in some other embodiments, the reflector and the transparent electrode in contact with each other may be collectively regarded as a reflector to provide the reflection for light emitted from the organic light-emitting layer on a side of the electrode. To simplify the description, the descriptions of “reflectance provided by disposing the reflector”, “reflectance provided by the reflector when disposed to reflect light emitted from the organic light-emitting layer”, or similar descriptions herein include reflectance provided by any possible situation in which the reflector generates reflection.

In some embodiments, the reflectors 281, 282, and 283 are disposed to have a reflectance of 30% or more (or a transmittance of 70% or less), for example, 30% or more, 35% or more, 40% or more, 45% or more, 50% or more, 55% or more, 60% or more, 65% or more, or 70% or more for light emitted from organic light-emitting layers 260A, 260B, and 260C. The higher the reflectance, the better the color purity of the light, and the smaller the light diffusion angle of the organic light-emitting device.

In some embodiments, when the reflectance provided by the reflectors 281, 282, and 283 exceeds 30%, full width at half maximum (FWHM) of emission peak spectrum of the organic light-emitting layer can be reduced. In some embodiments, when the reflectance provided by the reflectors 281, 282, and 283 is 30% or more, the FWHM of the emission peak spectrum of the organic light-emitting layer can be reduced by 10% or more. In some embodiments, when the reflectance provided by the reflectors 281, 282, and 283 is 40% or more, the FWHM of the emission peak spectrum of the organic light-emitting layer can be reduced by 15% or more. In some embodiments, when the reflectance provided by reflectors 281, 282, and 283 is 50% or more, the FWHM of the emission peak spectrum of the organic light-emitting layer can be reduced by 20% or more. In some embodiments, when the reflectance provided by reflectors 281, 282, and 283 is 60% or more, the FWHM of the emission peak spectrum of the organic light-emitting layer can be reduced by 25% or more.

In some embodiments, when the reflectance provided by the reflectors 281, 282, and 283 is 30% or more, the emission diffusion angle of the organic light-emitting layer is about ±60 degrees or less. In some embodiments, when the reflectance provided by the reflectors 281, 282, and 283 is 40% or more, the emission diffusion angle of the organic light-emitting layer is about ±50 degrees or less. In some embodiments, when the reflectance provided by the reflectors 281, 282, and 283 is 50% or more, the emission diffusion angle of the organic light-emitting layer is about ±40 degrees or less. In some embodiments, when the reflectance provided by the reflectors 281, 282, and 283 is 60% or more, the emission diffusion angle of the organic light-emitting layer is about ±30 degrees or less.

In some embodiments, the reflectors 281, 282, and 283 may be connected to each other. In some embodiments, the reflectors 281, 282, and 283 may be disposed to be separated. In some embodiments, the reflectors 281, 282, and 283 each include reflective metal or non-conductive reflective material. In some embodiments, the greater the thickness of the reflectors 281, 282, and 283, the higher the reflectance. In some embodiments, the reflectors 281, 282, and 283 each include silver, a distributed Bragg reflector (DBR), or other suitable reflective materials.

In some embodiments, a DBR is formed by alternately stacking multiple layers of dielectric materials having different refractive indices. In some embodiments, the more layers in the DBR, the higher the reflectance of the DBR.

In some non-limiting embodiments where the DBR structure is used as the reflector 281, the reflector 281 includes a plurality of dielectric material layers 281-1, 281-2, 281-3, and 281-4 formed from bottom to top between the substrate 100 and the electrode 215, where the refractive index of the dielectric material layer 281-1 is different from the refractive index of the dielectric material layer 281-2, and the refractive index of the dielectric material layer 281-3 is different from the refractive index of the dielectric material layer 281-4. A low refractive index dielectric material layer and a high refractive index dielectric material layer may form a DBR pair. In some embodiments, the refractive index difference between the dielectric material layer 281-1 and the dielectric material layer 281-2 is 0.4 or more. In some embodiments, the refractive index difference between the dielectric material layer 281-3 and the dielectric material layer 281-4 is 0.4 or more. In some embodiments, the refractive index of the dielectric material layer 281-1 is the same as or different from the refractive index of the dielectric material layer 281-3. In some embodiments, the refractive index of the dielectric material layer 281-2 is the same as or different from the refractive index of the dielectric material layer 281-4. In some embodiments, the reflector 281 has a total thickness H-R1. Moreover, although two DBR pairs are used as an example for the reflector 281 in the figure, the present disclosure is not limited thereto; in some embodiments, the reflector 281 may include a single or multiple DBR pairs to increase the reflectance on the anode side of the organic light-emitting unit 101.

In some non-limiting embodiments where the DBR structure is used as the reflector 282, the reflector 282 includes a plurality of dielectric material layers 282-1, 282-2, 282-3, and 282-4 formed from bottom to top between the substrate 100 and the electrode 225, where the refractive index of the dielectric material layer 282-1 is different from the refractive index of the dielectric material layer 282-2, and the refractive index of the dielectric material layer 282-3 is different from the refractive index of the dielectric material layer 282-4. A low refractive index dielectric material layer and a high refractive index dielectric material layer may form a DBR pair. In some embodiments, the refractive index difference between the dielectric material layer 282-1 and the dielectric material layer 282-2 is 0.4 or more. In some embodiments, the refractive index difference between the dielectric material layer 282-3 and the dielectric material layer 282-4 is 0.4 or more. In some embodiments, the refractive index of the dielectric material layer 282-1 is the same as or different from the refractive index of the dielectric material layer 282-3. In some embodiments, the refractive index of the dielectric material layer 282-2 is the same as or different from the refractive index of the dielectric material layer 282-4. In some embodiments, the reflector 282 has a total thickness H-R2. Moreover, the reflector 282 is not limited to the example of two DBR pairs. In some embodiments, the reflector 282 may include one or more DBR pairs to provide reflectance on the anode side of the organic light-emitting unit 102.

Moreover, the reflectance provided by disposing the reflector 282 may be different from or the same as the reflectance provided by disposing the reflector 281. In some embodiments, the refractive index difference of the dielectric material layers of each DBR pair in the reflector 282 may be different from or the same as the refractive index difference of the dielectric material layers of each DBR pair in the reflector 281. In some embodiments, the number of DBR pairs in the reflector 282 may be different from or the same as the number of DBR pairs in the reflector 281. In some embodiments, the total thickness H-R2 of the reflector 282 may be different from or the same as the total thickness H-R1 of the reflector 281.

In some non-limiting embodiments where a DBR structure is used as the reflector 283, the reflector 283 includes a plurality of dielectric material layers 283-1, 283-2, 283-3, and 283-4 formed from bottom to top between the substrate 100 and the electrode 235, where the refractive index of the dielectric material layer 283-1 is different from the refractive index of the dielectric material layer 283-2, and the refractive index of the dielectric material layer 283-3 is different from the refractive index of the dielectric material layer 283-4. A low refractive index dielectric material layer and a high refractive index dielectric material layer can form a DBR pair. In some embodiments, the refractive index difference between the dielectric material layer 283-1 and the dielectric material layer 283-2 is 0.4 or more. In some embodiments, the refractive index difference between the dielectric material layer 283-3 and the dielectric material layer 283-4 is 0.4 or more. In some embodiments, the refractive index of the dielectric material layer 283-1 is the same as or different from the refractive index of the dielectric material layer 283-3. In some embodiments, the refractive index of the dielectric material layer 283-2 is the same as or different from the refractive index of the dielectric material layer 283-4. In some embodiments, the reflector 283 has a total thickness H-R3. Moreover, the reflector 283 is not limited to the example of two DBR pairs. In some embodiments, the reflector 283 may include one or more DBR pairs to provide reflectance on the anode side of the organic light-emitting unit 103.

Moreover, in some embodiments, the reflectance provided by the reflector 283 may be different from or the same as the reflectance provided by the reflector 282. In some embodiments, the reflectance provided by the reflector 283 may be different from or the same as the reflectance provided by the reflector 281. In some embodiments, the refractive index difference of the dielectric material layers of each DBR pair in the reflector 283 may be different from or the same as the refractive index difference of the dielectric material layers of each DBR pair in the reflector 282. In some embodiments, the refractive index difference of the dielectric material layers of each DBR pair in the reflector 283 may be different from or the same as the refractive index difference of the dielectric material layers of each DBR pair in the reflector 281. In some embodiments, the number of DBR pairs in the reflector 283 may be different from or the same as the number of DBR pairs in the reflector 282, and different from or the same as the number of DBR pairs in the reflector 281.

Moreover, in some embodiments, the greater the thickness of the reflector, the higher the reflectance. In some embodiments, the total thickness H-R3 of the reflector 283 may be different from or the same as the total thickness H-R1 of the reflector 281. In some embodiments, the total thickness H-R3 of the reflector 283 may be different from or the same as the total thickness H-R2 of the reflector 282. In some embodiments where a DBR structure is used as a reflector, the reflectance of the reflector is determined by the refractive index difference of the dielectric material layers forming the DBR and the number of DBR periods. The more DBR pairs (also known as DBR periods) there are, the greater the thickness of the reflector, and the higher the reflectance.

In some embodiments, the spacer structure 30 is located on the substrate 100 and partially covers the electrodes 215, 225, and 235. In some embodiments, the spacer structure 30 is located between the organic light-emitting layers 260A, 260B, and 260C. In some embodiments, the spacer structure 30 may include bumps 310. In some embodiments, the pattern of the spacer structure 30 is designed according to the pixel arrangement. In some embodiments, the spacer structure 30 serves as a pixel defined layer (PDL). In some embodiments, the bumps 310 define the pixel area. In some embodiments, each bump 310 fills a gap between two adjacent electrodes 215, 225, and 235. Each electrode 215, 225, and 235 is partially covered by the bump 310. In some embodiments, the spacer structure 30 includes an organic insulating material. In some embodiments, the spacer structure 30 includes a photosensitive material. In some embodiments, the spacer structure 30 may further include quantum dots, which have excellent light absorption efficiency. In some embodiments, the spacer structure 30 may further include carbon black materials, such as carbon black nanoparticles, conductive fibers including carbon black, or the like. In some embodiments, the spacer structure 30 may further include black body materials, which have an absorptivity of 90%, 95%, 99%, 99.5%, or 99.9% or more for visible light.

In some embodiments, the absorptivity of the spacer structure 30 for a specific wavelength is greater than or equal to 50%, or greater than or equal to 60%, or greater than or equal to 70%, or greater than or equal to 80%, or greater than or equal to 90%, or greater than or equal to 95%. In some embodiments, the specific wavelength is not greater than 400 nm. In some embodiments, the specific wavelength is not greater than 350 nm. In some embodiments, the specific wavelength is not greater than 300 nm. In some embodiments, the specific wavelength is not greater than 250 nm. In some embodiments, the specific wavelength is not greater than 200 nm. In some embodiments, the specific wavelength is not greater than 150 nm. In some embodiments, the specific wavelength is not greater than 100 nm.

In some embodiments, the cover layer 40 includes a capping layer 410, an encapsulation layer 420, a filling layer 430, and a cover plate 440. In some embodiments, the capping layer 410 is disposed on the electrode 216 and is substantially conformal with a non-planar upper surface of the electrode 216. The capping layer 410 may include a dielectric material or an inorganic insulating material, such as silicon oxide. In some embodiments, the capping layer 410 may include a hole transport layer material for extracting light lost inside the organic light-emitting device to increase luminous efficiency. The capping layer 410 may also be referred to as a light extraction layer.

In some embodiments, the encapsulation layer 420 is disposed on the capping layer 410 and is substantially conformal with a non-planar upper surface of the capping layer 410. The encapsulation layer 420 may include oxides, such as silicon oxide. In some embodiments, the encapsulation layer 420 is substantially conformal with a non-planar upper surface of the capping layer 410 and has a plurality of recesses corresponding to the organic light-emitting layers 260A, 260B, and 260C. The encapsulation layer 420 may include polymer organic materials, such as epoxy-based materials.

In some embodiments, the filling layer 430 is disposed on the encapsulation layer 420, and a lower surface of the filling layer 430 is substantially conformal with a non-planar upper surface of the encapsulation layer 420. The filling layer 430 may also be referred to as a planarization layer. The filling layer 430 may include polymer organic materials, such as epoxy resin.

In some embodiments, the cover plate 440 is disposed on a planar upper surface of the filling layer 430. The cover plate 440 may also be referred to as a protective layer. The cover plate 440 may include a transparent hard cover plate, such as a glass plate. The cover plate 440 may be used to prevent components of the organic light-emitting device from contacting external moisture, which may cause the components failure and fail to emit light.

In some embodiments, the inorganic barrier layer 268 is located between the electrodes 215, 225, and 235 and the organic light-emitting layers 260A, 260B, and 260C. In some embodiments, a side surface of the inorganic barrier layer 268 is in contact with the bump 310. In some embodiments, the inorganic barrier layer 268 substantially completely covers interfaces between the electrodes 215, 225, and 235 and the organic light-emitting layers 260A, 260B, and 260C. In some embodiments, the inorganic barrier layer 268 includes transition metal oxides. In some embodiments, the inorganic barrier layer 268 includes molybdenum oxide (MoO₃). In some embodiments, a thickness of the inorganic barrier layer 268 is equal to or less than 100 angstroms. In some embodiments, a ratio of the thickness of the inorganic barrier layer 268 to a thickness of the electrodes 215, 225, and 235 is less than 0.1, 0.06, or 0.03. In some embodiments, the inorganic barrier layer 268 and the hole injection layers 261A and 261B may together form a hole injection layer of the organic light-emitting layers 260A, 260B, and 260C.

In some embodiments, the inorganic barrier layer 270 is in contact with the capping layer 410. In some embodiments, the inorganic barrier layer 270 covers the electrode 216. In some embodiments, the capping layer 410 is located on the inorganic barrier layer 270 and is separated from the electrode 216 through the inorganic barrier layer 270. In some embodiments, the inorganic barrier layer 270 substantially completely covers an interface between the electrode 216 and the capping layer 410. In some embodiments, the inorganic barrier layer 270 includes transition metal oxides. In some embodiments, the inorganic barrier layer 270 includes molybdenum oxide (MoO₃). In some embodiments, a thickness of the inorganic barrier layer 270 is equal to or less than 100 angstroms. In some embodiments, a ratio of the thickness of the inorganic barrier layer 270 to a thickness of the electrode 216 is less than 0.15, 0.1, or 0.05. In some embodiments, a ratio of the thickness of the inorganic barrier layer 270 to a thickness of the capping layer 410 is less than 0.5, 0.3, or 0.15.

According to some embodiments of the present disclosure, as shown in FIG. 2A, through the design of disposing the reflectors 281, 282, 283 on a surface of a transparent electrode (such as the electrodes 215, 225, 235 shown in FIG. 2A, serving as the anode), the reflectance of the anode can be increased, the resonant cavity strength of the organic light-emitting device 10A can be enhanced, so that a purity of the emitted light color can be improved and a diffusion angle of the emitted light can be reduced.

Moreover, according to some embodiments of the present disclosure, as shown in FIG. 2A, through the design of disposing the reflectors on an outer surface of the transparent electrode, the optical length of the resonant cavity can be further increased, so that the optical length of the resonant cavity is increased from a distance between a lower surface of an upper electrode and an upper surface of a lower electrode (e.g., a lower surface of the electrode 216 and an upper surface of the electrodes 215, 225, 235) to a distance between a lower surface of the upper electrode and a lower surface of the lower electrode (e.g., the lower surface of the electrode 216 and a lower surface of the electrodes 215, 225, 235), or to a distance between the lower surface of the upper electrode and an interior of the reflector (depending on the material of the reflector); that is, the optical length of the resonant cavity is at least increased by a thickness of the lower electrode (e.g., the electrodes 215, 225, 235). As such, the optical length of the resonant cavity can be adjusted by adjusting the thickness of the transparent electrode.

Additionally, when the organic light-emitting layers 260A, 260B, and 260C emit light of different colors, the optimal optical lengths of the resonant cavities of their pixel units differ. According to some embodiments of the present disclosure, by adjusting the thickness of the electrodes 215, 225, 235 (transparent electrodes shown in the example in FIG. 2A), or the reflectance of the reflectors (e.g., by adjusting their thickness or adjusting a composition of a single or multiple film layers), or by adjusting and matching both simultaneously, the optimal resonant cavity effect for the pixel units of each color can be achieved, thereby improving the optical performance of the organic light-emitting device 10A.

Moreover, according to some embodiments of the present disclosure, the inorganic barrier layer 268 can be used to prevent metal atoms in the electrode 215 from diffusing into the organic light-emitting layers 260A, 260B, and 260C (e.g., the hole injection layer 261, the hole transport layer 262, the electron blocking layer 263, and the organic emission layer 264) to avoid quenching, thereby preventing a decrease in luminous efficiency, thereby enhancing a luminous brightness of the organic light-emitting device and improving color rendering index (RA). Moreover, according to some embodiments of the present disclosure, the inorganic barrier layer 268 has a very thin thickness relative to the electrodes 215, 225, and 235, so it does not significantly increase the thickness dimension of the organic light-emitting device, nor does it adversely extend the light path.

Additionally, according to some embodiments of the present disclosure, the inorganic barrier layer 270 can be used to prevent metal atoms in the electrode 216 from diffusing into the organic layer (e.g., the capping layer 410) to avoid a decrease in luminous efficiency, thereby enhancing a luminous brightness of the organic light-emitting device and improving color rendering index (RA). Moreover, according to some embodiments of the present disclosure, the inorganic barrier layer 270 has a very thin thickness relative to the electrode 216 and the capping layer 410, so it does not significantly increase the thickness of the organic light-emitting device, nor does it adversely extend the light path.

FIG. 2B is a cross-sectional view illustrating an organic light-emitting component 10B. The structure of FIG. 2B is similar to that of FIG. 2A, with the difference being that in FIG. 2B, the reflector 281 is disposed between the electrode 215 and the organic light-emitting layer 260A, the reflector 282 is disposed between the electrode 225 and the organic light-emitting layer 260B, and the reflector 283 is deposed between the electrode 235 and the organic light-emitting layer 260C, to provide reflection for light emitted from the organic light-emitting layer on this electrode side (as the anode), increasing reflectance to enhance the resonant cavity strength of the organic light-emitting component 10B, so that the purity of the emitted light color can be improved and the diffusion angle of the emitted light can be reduced. Please refer to the description of FIG. 2A for the other components.

FIG. 2C is a cross-sectional view illustrating an organic light-emitting device 10C. In some embodiments, FIG. 2C illustrates a cross-sectional view of the organic light-emitting device 10C of FIG. 1. In some embodiments, FIG. 2C illustrates a cross-sectional view along the line 1A-1A’ in FIG. 1. In some embodiments, FIG. 2C illustrates a cross-sectional view along the line 1A-1A’ in FIG. 1 and only illustrate the light-emitting region. The structure of FIG. 2C is similar to that of FIG. 2A, with the differences described as follows.

In some embodiments, the organic light-emitting device 10C includes a substrate 100, an electrode 215, an electrode 225, an electrode 235, an electrode 216, reflectors 281, 282, and 283, a light-emitting layer 20, an inorganic barrier layer 268, an inorganic barrier layer 270, a spacer structure 30, and a cover layer 40. In some embodiments, the electrodes 215, 225, and 235 are metal electrodes, and the electrode 216 is a transparent electrode. In some embodiments, the electrodes 215, 225, and 235 have thicknesses T1, T2, and T3, respectively. The thicknesses of the electrodes 215, 225, and 235 may be the same or different.

In some embodiments, surfaces 2151, 2251, and 2351 of the electrodes 215, 225, and 235 facing the electrode 216 provide high-reflectance reflective surfaces, for example, with a reflectance of 80% or more (e.g., 80% or more, 85% or more, 90% or more, or 95% or more) for the light emitted from the organic light-emitting layers 260A, 260B, and 260C.

In some embodiments, the electrode 216 is a transparent electrode, for example, including ITO, IZO, or other suitable materials, and the reflectors 281, 282, and 283 (including surfaces 281a, 282a, 283a) are disposed on a surface of the electrode 216 to increase the light reflectance on a side of the electrode 216, achieving a resonant cavity effect. In some embodiments, the electrode 216 is located between the reflectors 281, 282, 283, and the electrodes 215, 225, and 235. In some embodiments, a light-emitting surface of the organic light-emitting device 10C is a surface 440a of the cover plate 440. In some embodiments, the reflectors 281, 282, 283 are disposed to have a reflectance of 30% or more (or a transmittance of 70% or less), for example, 30% or more, 35% or more, 40% or more, 45% or more, 50% or more, 55% or more, 60% or more, 65% or more, or 70% or more for the light emitted from the organic light-emitting layers 260A, 260B, 260C. The higher the reflectance, the better the color purity, and the smaller the light diffusion angle of the organic light-emitting device.

According to some embodiments of the present disclosure, through the design of disposing reflectors (such as the reflectors 281, 282, 283 shown in FIG. 2C) on a surface of a transparent electrode (such as the electrode 216 shown in FIG. 2C, serving as the cathode), the reflectance of the cathode can be increased, enhancing the resonant cavity strength of the organic light-emitting device 10C, so that the purity of the emitted light color can be improved, and the diffusion angle of the emitted light can be reduced.

Moreover, according to some embodiments of the present disclosure as shown in FIG. 2C, through the design of disposing the reflectors on an outer surface of the transparent electrode, the optical length of the resonant cavity can be further increased, so that the optical length of the resonant cavity is increased from a distance between a lower surface of an upper electrode and an upper surface of a lower electrode to a distance between an upper surface of the electrode and an upper surface of the lower electrode (e.g., the upper surface of the transparent electrode 216 and the upper surfaces of the metal electrodes 215, 225, 235 in the example of FIG. 2C), or to a distance between an interior of the reflector and the upper surface of the lower electrode (depending on the material of the reflector); that is, the optical length of the resonant cavity is at least increased by a thickness of the upper electrode (e.g., the electrode 216). As such, the optical length of the resonant cavity can be adjusted by adjusting the thickness of the transparent electrode.

In addition, when the organic light-emitting layers 260A, 260B, and 260C emit light of different colors, the optimal optical lengths of the resonant cavities of the pixel units differ. According to some embodiments of the present disclosure, by adjusting the thickness of the electrodes 215, 225, 235 (such as the metal electrodes in the example of FIG. 2C), or the reflectance of the reflectors (e.g., by adjusting their thickness or adjusting a composition of a single or multiple film layer materials), or by adjusting and matching both simultaneously, the optimal resonant cavity effect for the pixel units of each color can be achieved, thereby improving the optical performance of the organic light-emitting device 10C.

FIG. 2D is a cross-sectional view illustrating an organic light-emitting component 10D. The structure of FIG. 2D is similar to the structure of FIG. 2C, with the difference being that in FIG. 2D, the reflector 281 is disposed between the electrode 215 and the organic light-emitting layer 260A, the reflector 282 is disposed between the electrode 225 and the organic light-emitting layer 260B, and the reflector 283 is disposed between the electrode 235 and the organic light-emitting layer 260C, to provide reflection for the light emitted from the organic light-emitting layer on the side of this electrode 216 (serving as the cathode), increasing reflectance to enhance the resonant cavity strength of the organic light-emitting component 10D, so that the purity of the emitted light color can be improved, and the diffusion angle of the emitted light can be reduced. Please refer to the description of FIG. 2C for the other components.

FIG. 2E is a cross-sectional view illustrating an organic light-emitting device 10E. In some embodiments, FIG. 2E illustrates a cross-sectional view of the organic light-emitting device 10E in FIG. 1. In some embodiments, FIG. 2E illustrates a cross-sectional view along line the 1A-1A’ in FIG. 1. In some embodiments, FIG. 2E illustrates a cross-sectional view along the line 1A-1A’ in FIG. 1 and only illustrate the light-emitting region. The structure of FIG. 2E is similar to that of FIG. 2A, with the differences described as follows.

In some embodiments, the organic light-emitting device 10E includes a substrate 100, an electrode 215, an electrode 225, an electrode 235, an electrode 216, a light-emitting layer 20, an inorganic barrier layer 268, a reflector 280, a reflector 281, a reflector 282, a reflector 283, an inorganic barrier layer 270, a spacer structure 30, and a cover layer 40. In some embodiments, the electrodes 215, 225, 235, and 216 are transparent electrodes, for example, including ITO, IZO, or other suitable materials. In some embodiments, reflectors are disposed on outer surfaces of the electrodes 215, 225, 235, and 216 to increase the reflectance of the transparent electrodes.

Specifically, in some embodiments, as shown in FIG. 2E, the reflectors 281, 282, 283 are disposed on an upper surface (or an outer surface) of the electrode 216, and include surfaces 281a, 282a, 283a, respectively. In some embodiments, the electrode 216 is in contact with the organic light-emitting layers 260A, 260B, and 260C. The electrode 216 may be a continuous film as shown in FIG. 2E, and is located above the organic light-emitting layers 260A, 260B, and 260C and the bump 310. In some embodiments, the reflector 280 is disposed between the electrodes 215, 225, 235, and the substrate 100.

In some embodiments, the reflectors 281, 282, 283 are disposed to have a reflectance of 30% or more (e.g., 30% or more, 35% or more, 40% or more, 45% or more, 50% or more, 55% or more, 60% or more, 65% or more, or 70% or more) for light emitted from the organic light-emitting layers 260A, 260B, and 260C, and the reflector 280 is disposed to have a reflectance of is 80% or more (e.g., 80% or more, 85% or more, 90% or more, or 95% or more) for light emitted from the organic light-emitting layers 260A, 260B, and 260C, where a light-emitting surface of the organic light-emitting device 10E is a surface 440a.

In some other embodiments, the reflectors 281, 282, and 283 are disposed to have a reflectance of 80% or more (e.g., 80% or more, 85% or more, 90% or more, or 95% or more) for the light emitted from the organic light-emitting layers 260A, 260B, and 260C, and the reflector 280 is disposed to have a reflectance of 30% or more (e.g., 30% or more, 35% or more, 40% or more, 45% or more, 50% or more, 55% or more, 60% or more, 65% or more, or 70% or more) for the light emitted from the organic light-emitting layers 260A, 260B, and 260C, where the light-emitting surface of the organic light-emitting device 10E is a surface 100b of the substrate 100.

In some embodiments, the reflectors 280, 281, 282, and 283 each include reflective metal or non-conductive reflective material. In some embodiments, the reflectors 280, 281, 282, and 283 each include silver, a distributed Bragg reflector (DBR), or other suitable reflective materials. The reflectors 280, 281, 282, and 283 may each include the same or different materials.

Furthermore, in some embodiments, the reflectors 281, 282, and 283 are non-continuous films and correspond to the regions above the organic light-emitting layers 260A, 260B, and 260C, respectively. The elevation of the upper surfaces of reflectors 281, 282, and 283, for example, does not excessively protrude above the upper surface of the entire light-emitting layer 20, such as not extending above the bump 310, which can reduce the stress on the local region above the bump 310 caused by the encapsulation layer 420 above the bump 310, effectively preventing the electrode 216 above the bump 310 from being broken due to stress caused by the extrusion between the upper material (the encapsulation layer 420 and the reflector) and the bump 310.

According to some embodiments of the present disclosure, through the design of disposing the reflectors 280, 281, 282, and 283 on the outer surface of the transparent electrode, the reflectance of the anode and cathode can be increased, enhancing the resonant cavity strength of the organic light-emitting device 10E, so that the purity of the emitted light color can be improved, and the diffusion angle of the emitted light can be reduced.

Moreover, similarly, according to some embodiments of the present disclosure, through the design of disposing reflectors (e.g., 281, 282, and 283 disposed on the surface of the transparent electrode 216 and the reflector 280 disposed on the surface of the transparent electrodes 215, 225, 235) on both sides of the transparent anode and the transparent cathode, the optical length of the resonant cavity can be further varied (e.g., increased). As such, the optical length of the resonant cavity can be adjusted by adjusting the thickness of the transparent electrodes.

When the organic light-emitting layers 260A, 260B, and 260C emit light of different colors, the optimal optical lengths of the resonant cavities of their pixel units differ. According to some embodiments of the present disclosure, by adjusting thicknesses of the transparent electrodes on both sides (such as the transparent electrodes 215, 225, 235, 216 shown in the example of FIG. 2E), or the reflectance of the reflectors, or by adjusting and matching both simultaneously, the optimal resonant cavity effect for the pixel units of each color can be achieved, thereby improving the optical performance of the organic light-emitting device 10E.

FIG. 2F is a cross-sectional view illustrating an organic light-emitting component 10F. The structure of FIG. 2F is similar to that of FIG. 2E, with the difference being that in FIG. 2F, the reflectors 281, 282, and 283 are disposed on the lower surface (or inner surface) of the electrode 216. Specifically, as shown in FIG. 2F, the reflector 281 is disposed between the electrode 216 and the organic light-emitting layer 260A (e.g., between the electrode 216 and the electron injection layer (EIL) 266), the reflector 282 is disposed between the electrode 216 and the organic light-emitting layer 260B, and the reflector 283 is disposed between electrode 216 and the organic light-emitting layer 260C. The reflector 280 in FIG. 2F is the same as in FIG. 2E, and is disposed between the electrodes 215, 225, 235, and the substrate 100. In this way, the reflectance of the anode and cathode is increased, and the resonant cavity strength of the organic light-emitting component 10F is enhanced, so that the purity of the emitted light color can be enhanced, and the diffusion angle of the emitted light can be reduced. Please refer to the description in FIG. 2E for the other components.

FIG. 2G is a cross-sectional view illustrating an organic light-emitting component 10G. The structure of FIG. 2G is similar to that of FIG. 2E, with the difference being that in FIG. 2G, the reflector 284 is disposed between the electrode 215 and the organic light-emitting layer 260A, the reflector 285 is disposed between the electrode 225 and the organic light-emitting layer 260B, and the reflector 286 is disposed between the electrode 235 and the organic light-emitting layer 260C. The reflectors 281, 282, and 283 in FIG. 2G are the same as in FIG. 2E, and is disposed on the upper surface (or outer surface) of the electrode 216. In this way, the reflectance of the anode and cathode is increased, the resonant cavity strength of the organic light-emitting component 10G is enhanced, so that the purity of the emitted light color can be enhanced, and the diffusion angle of the emitted light can be reduced. Please refer to the description in FIG. 2E for the other components.

FIG. 2H is a cross-sectional view illustrating an organic light-emitting component 10H. The structure of FIG. 2H is similar to that of FIG. 2E, with the difference being that the reflectors on both sides are disposed between the electrode and the organic light-emitting layer (i.e., on the inner surface of the electrode). Specifically, as shown in FIG. 2H, the reflector 281 is disposed between the electrode 216 and the organic light-emitting layer 260A (for example, between the electrode 216 and the electron injection layer (EIL) 266), the reflector 282 is disposed between the electrode 216 and the organic light-emitting layer 260B, and the reflector 283 is disposed between the electrode 216 and the organic light-emitting layer 260C. Moreover, the reflector 284 is disposed between the electrode 215 and the organic light-emitting layer 260A, the reflector 285 is disposed between the electrode 225 and the organic light-emitting layer 260B, and the reflector 286 is disposed between the electrode 235 and the organic light-emitting layer 260C. In this way, the reflectance of the anode and cathode is increased, the resonant cavity strength of the organic light-emitting component 10H is enhanced, so that the purity of the emitted light color can be enhanced, and the diffusion angle of the emitted light can be reduced. Please refer to the description in FIG. 2E for the other components.

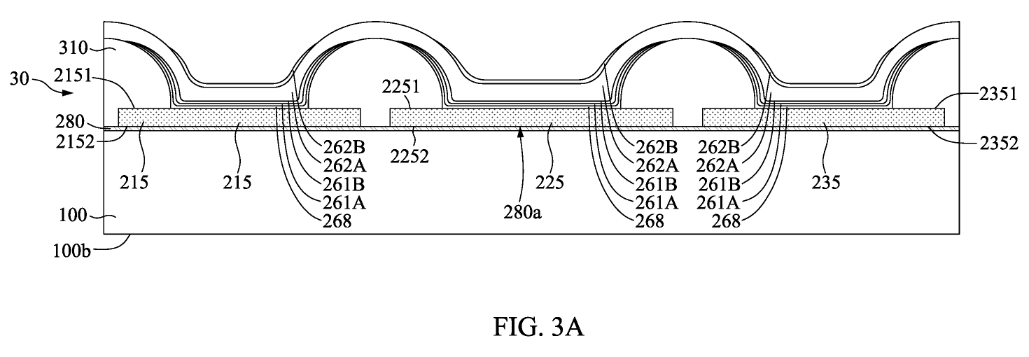

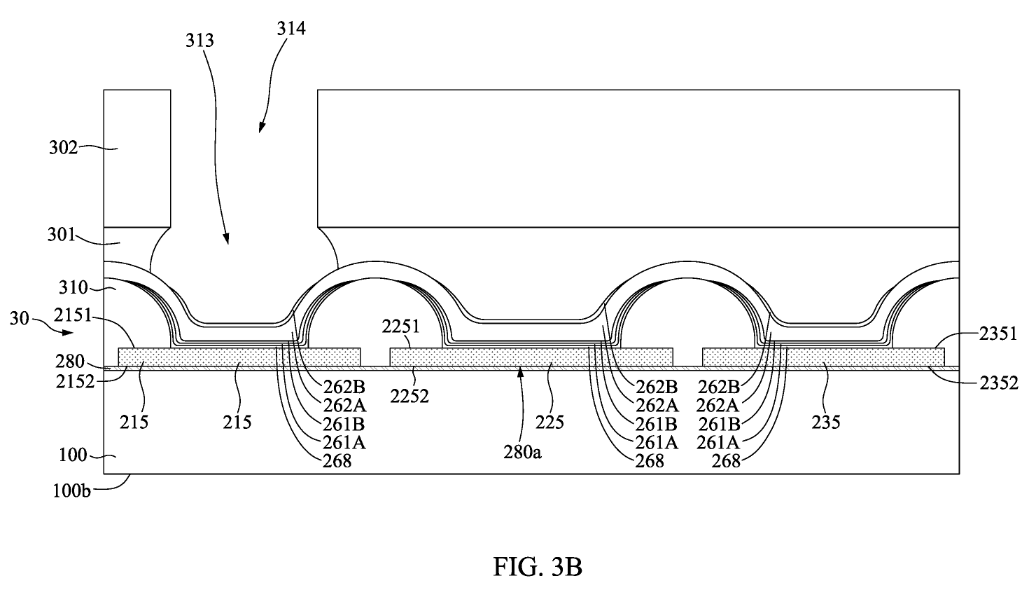

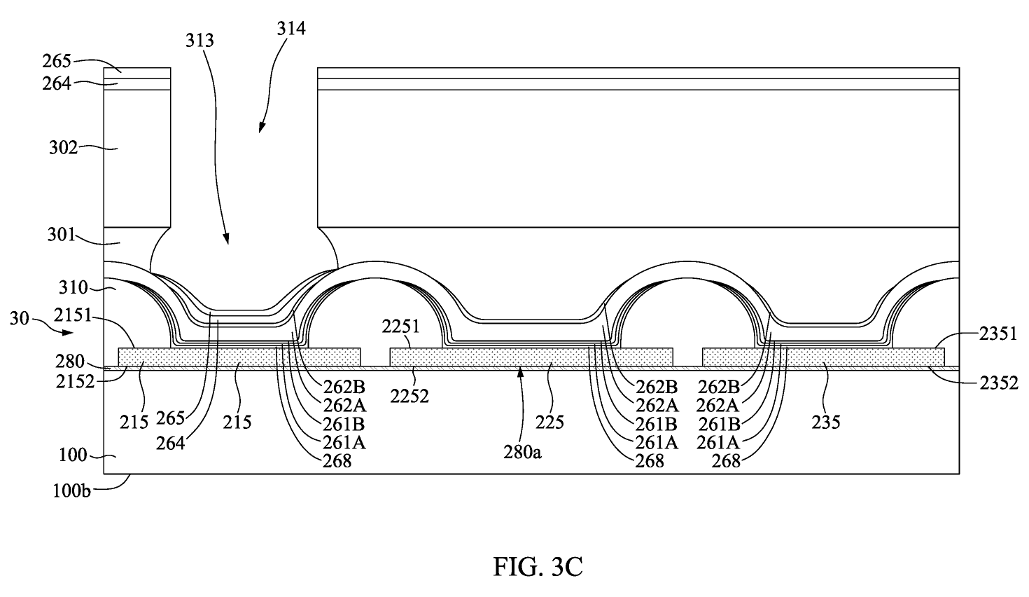

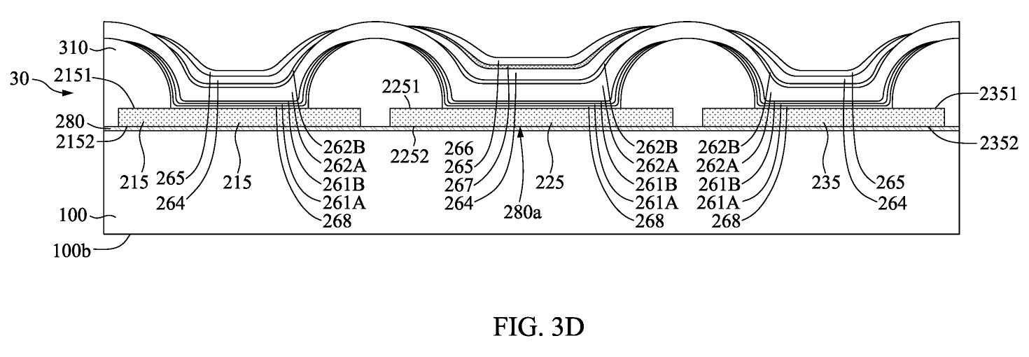

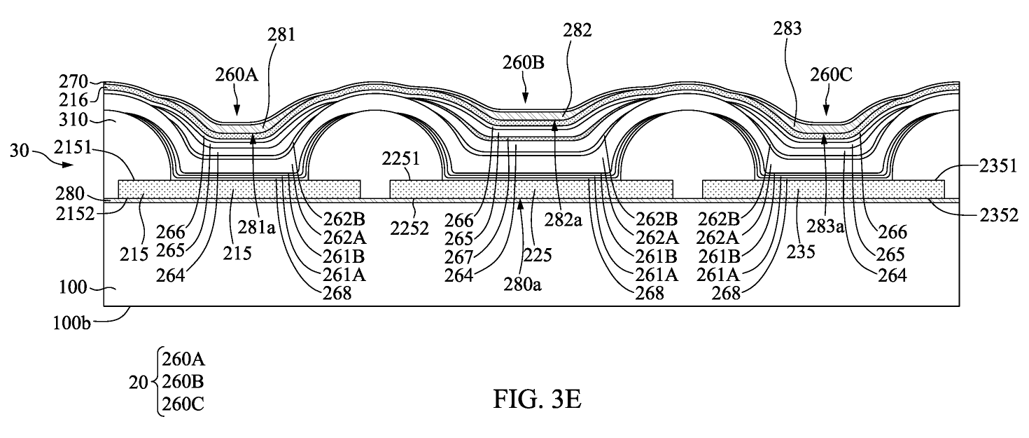

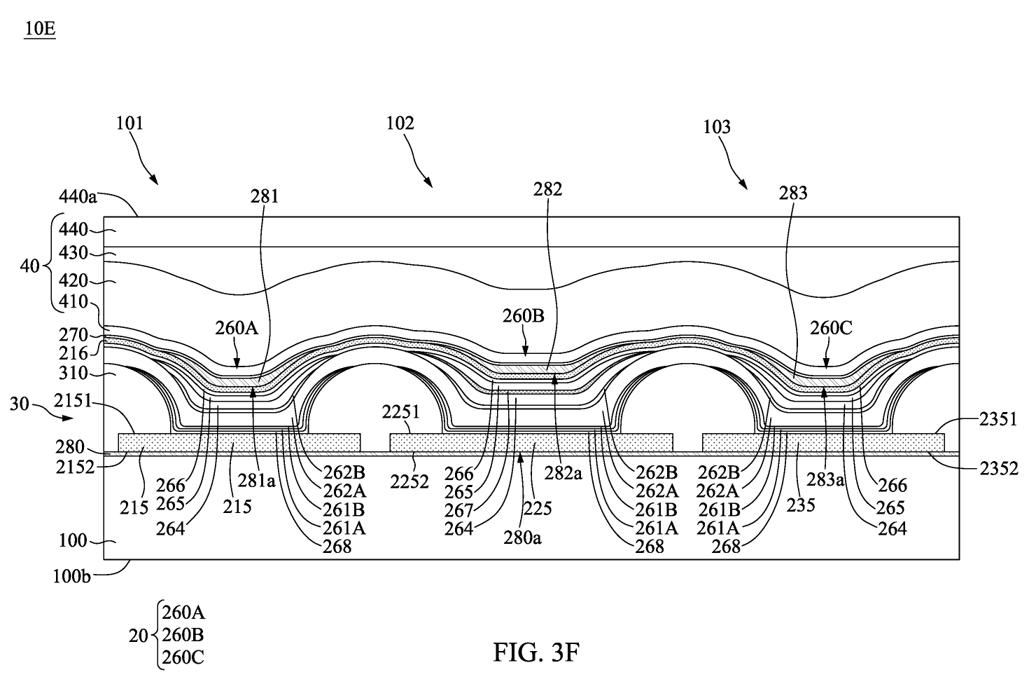

FIGS. 3A to 3F illustrate a manufacturing method of the organic light-emitting component 10E according to some embodiments.

As shown in FIG. 3A, in some embodiments, a substrate 100 is provided, a reflector 280 is disposed on the substrate 100, a plurality of electrodes 215, 225, and 235 are disposed, a plurality of bumps 310 (or spacer structures 30) are formed, and each bump 310 filling gaps between adjacent electrodes 215, 225, and 235. In some embodiments, transparent conductive materials are used to make the electrodes 215, 225, and 235.

Next, in some embodiments, an inorganic barrier layer 268, a hole injection layer (HIL) 261A, a hole injection layer (HIL) 261B, a hole transport layer (HTL) 262A, and a hole transport layer (HTL) 262B are disposed on surfaces of the bumps 310 and the electrodes 215, 225, and 235. In some embodiments, the inorganic barrier layer 268, the hole injection layer 261A, the hole injection layer 261B, the hole transport layer 262A, and the hole transport layer 262B are formed through evaporation. In some embodiments, the inorganic barrier layer 268, the hole injection layer 261A, the hole injection layer 261B, the hole transport layer 262A, and the hole transport layer 262B are evaporated comprehensively above the electrodes 215, 225, and 235, and due to thin thicknesses of the inorganic barrier layer 268, the hole injection layer 261A, the hole injection layer 261B, and the hole transport layer 262B, these layers above each electrode 215, 225, and 235 are disconnected by the bumps 310. Due to a thicker thickness of the hole transport layer 262A, the formed hole transport layer 262A continuously extends above the electrodes 215, 225, and 235 and the bumps 310.

As shown in FIG. 3B, in some embodiments, a buffer layer 301 is disposed on the bumps 310, and the buffer layer 301 also covers the inorganic barrier layer 268, the hole injection layer 261A, the hole injection layer 261B, the hole transport layer 262A, the hole transport layer 262B, and the electrodes 215, 225, and 235. The buffer layer 301 is used to block moisture from penetrating into the bumps 310 and the inorganic barrier layer 268, the hole injection layer 261A, the hole injection layer 261B, the hole transport layer 262A, and the hole transport layer 262B. Next, in some embodiments, a photosensitive layer 302 is disposed on the buffer layer 301, forming the buffer layer 301 and the photosensitive layer 302 through coating.

Next, in some embodiments, the photosensitive layer 302 is patterned through a lithography process to expose a portion of the buffer layer 301 through a recess 314. Then, a portion of the buffer layer 301 is removed (e.g., through a wet etching process) to form a recess 313, exposing the hole transport layer 262B.

As shown in FIG. 3C, in some embodiments, an organic emission layer (EM) 264 is disposed on the hole transport layer 262B, and then an electron transport layer (ETL) 265 is disposed on the organic emission layer (EM) 264. In some embodiments, the organic emission layer 264 and the electron transport layer 265 are formed through evaporation.

As shown in FIG. 3D, in some embodiments, the buffer layer 301, the photosensitive layer 302, and portions of the organic emission layer 264 and the electron transport layer 265 above the photosensitive layer 302 are removed. In some embodiments, the buffer layer 301, the photosensitive layer 302, portions of the organic emission layer 264, and portions of the electron transport layer 265 are removed through a wet etching process. In some embodiments, the steps described in FIG. 3B to FIG. 3C are repeated to form the organic emission layer 264, the hole blocking layer (HBL) 267, and the electron transport layer 265 on the electrode 225, and to form the organic emission layer 264 and the electron transport layer 265 on the electrode 235.

As shown in FIG. 3E, in some embodiments, an electron injection layer (EIL) 266 is disposed on the bump 310 and the electron transport layer 265. At this point, organic light-emitting layers 260A, 260B, and 260C (or light-emitting layer 20) are formed. Next, in some embodiments, an electrode 216 is disposed on the organic light-emitting layers 260A, 260B, and 260C and the spacer structure 30. In some embodiments, the electrode 216 is made using a transparent conductive material.

Next, in some embodiments, reflectors 281, 282, and 283 are disposed above the electrode 216. In some embodiments, the reflectors 281, 282, and 283 have surfaces 281a, 282a, and 283a, respectively, in contact with the electrode 216. In some embodiments, the reflectors 281, 282, and 283 correspond to the regions above the organic light-emitting layers 260A, 260B, and 260C, respectively. Next, in some embodiments, an inorganic barrier layer 270 is disposed above the electrode 216, and the inorganic barrier layer 270 covers the reflectors 281, 282, and 283. At this point, organic light-emitting units 101, 102, and 103 are formed.

As shown in FIG. 3F, in some embodiments, a capping layer 410 is disposed on the inorganic barrier layer 270 (e.g., through evaporation). Next, in some embodiments, an encapsulation layer 420 is disposed on the capping layer 410. In some embodiments, the encapsulation layer 420 is formed through plasma-enhanced chemical vapor deposition (PECVD). Next, in some embodiments, a filling layer 430 is disposed on the encapsulation layer 420. The filling layer 430 may fill recesses of the encapsulation layer 420 and provide a flat surface. Next, a cover plate 440 is disposed on the filling layer 430. As shown in FIG. 3F, at this point, the organic light-emitting device 10E as shown in FIG. 2E is formed.

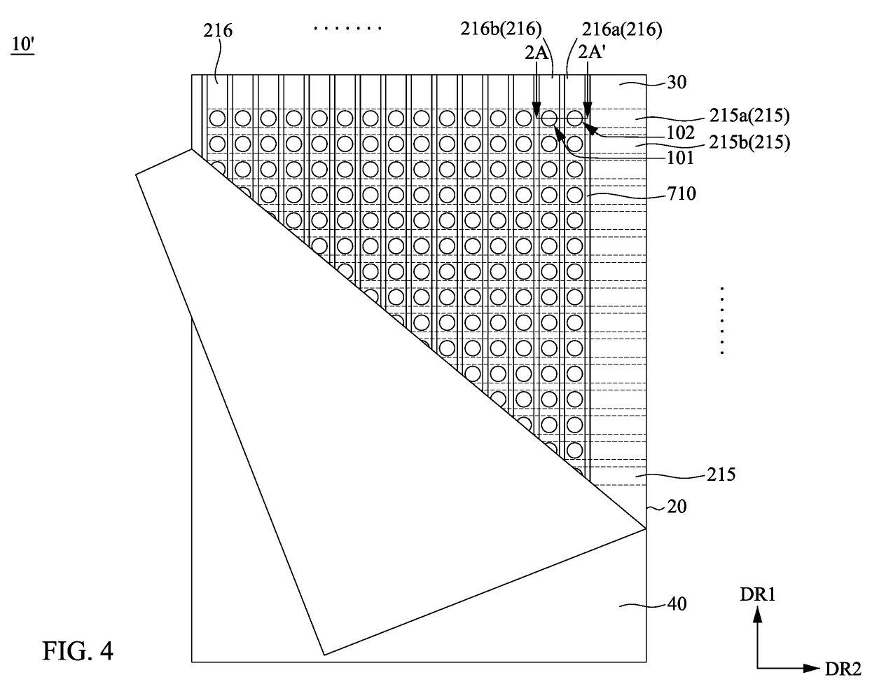

FIG. 4 is a top view illustrating an intermediate product of an organic light-emitting device 10’. The organic light-emitting device 10’ may include a light-emitting layer 20 and a cover layer 40 above the light-emitting layer 20. For the light-emitting layer 20, a spacer structure 30 may be designed to provide an array of recesses for accommodating the array of light-emitting pixels. The spacer structure 30, for example, serves as a pixel definition layer (PDL). In some embodiments, the spacer structure 30 may include bumps 310. In some embodiments, the bumps 310 define the pixel area. In some embodiments, the spacer structure 30 may include photosensitive material. The structure in FIG. 4 is similar to that of FIG. 1, with differences as described below.

As shown in FIG. 4, the organic light-emitting device 10’ may further include a plurality of electrodes 215 and a plurality of electrodes 216, such as electrodes 215a, 215b, and electrodes 216a, 216b. In some embodiments, the electrode 215 is an anode, and the electrode 216 is a cathode. In some embodiments, an extension direction DR2 of the electrode 215 is substantially perpendicular to an extension direction DR1 of the electrode 216. The organic light-emitting device 10’ may further include a blocking strip 710. In some embodiments, the extension direction DR1 of the electrode 216 is substantially parallel to the extension direction DR1 of the blocking strip 710.

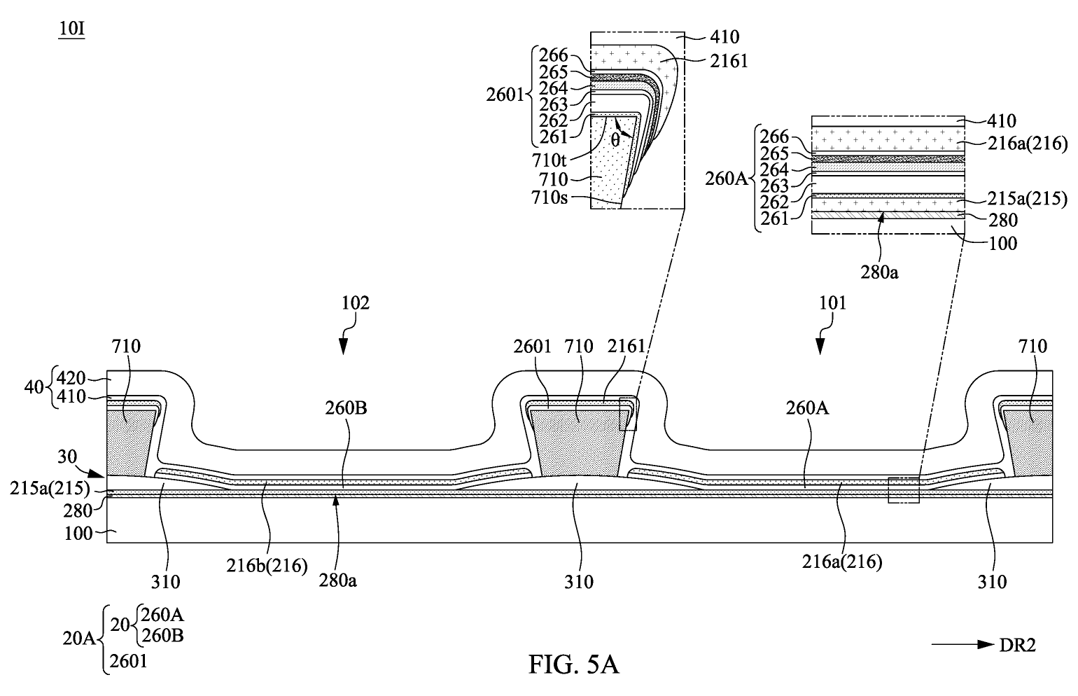

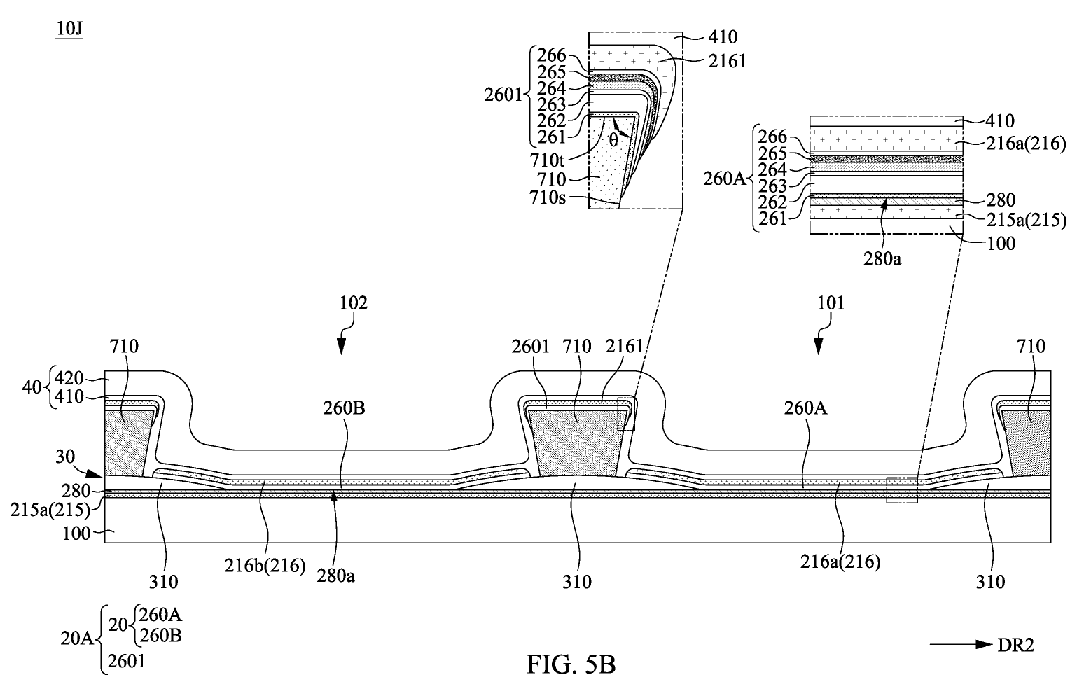

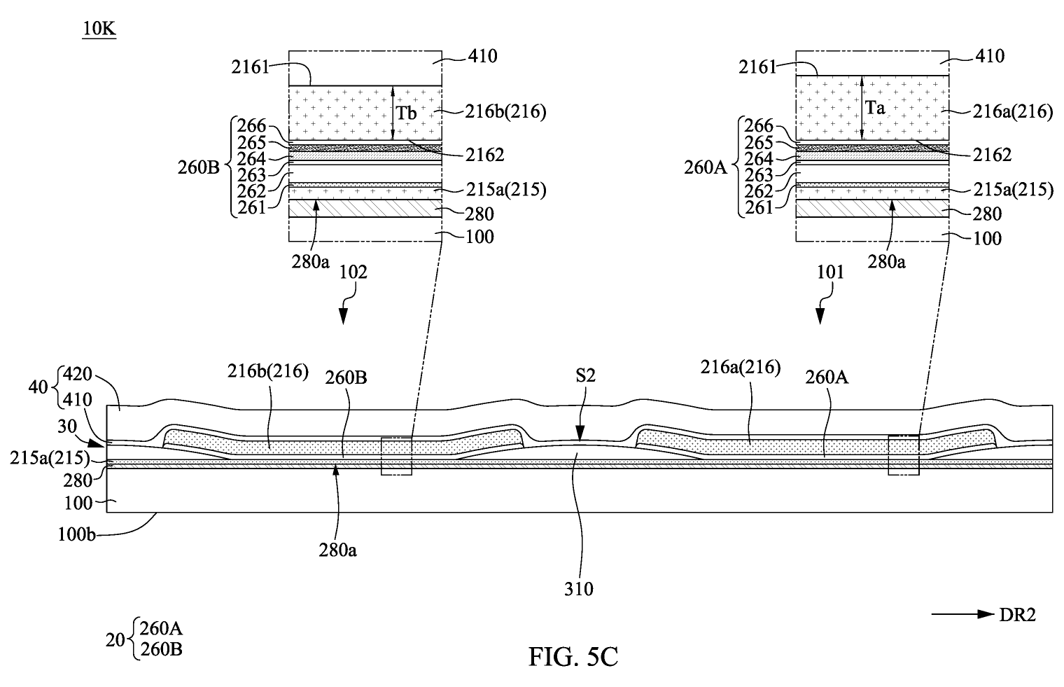

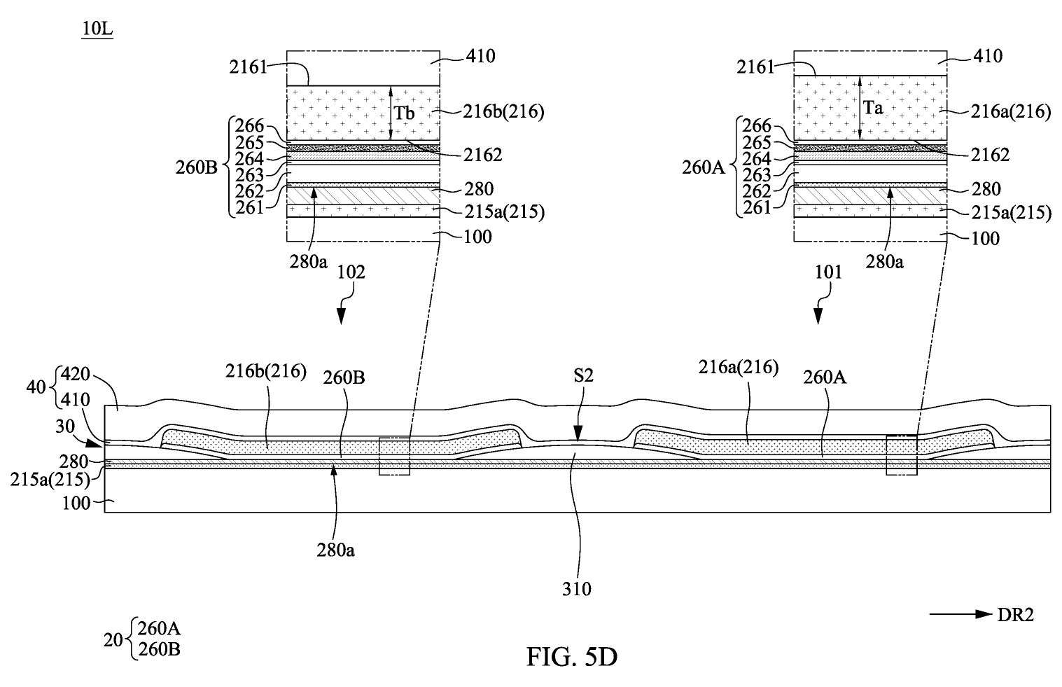

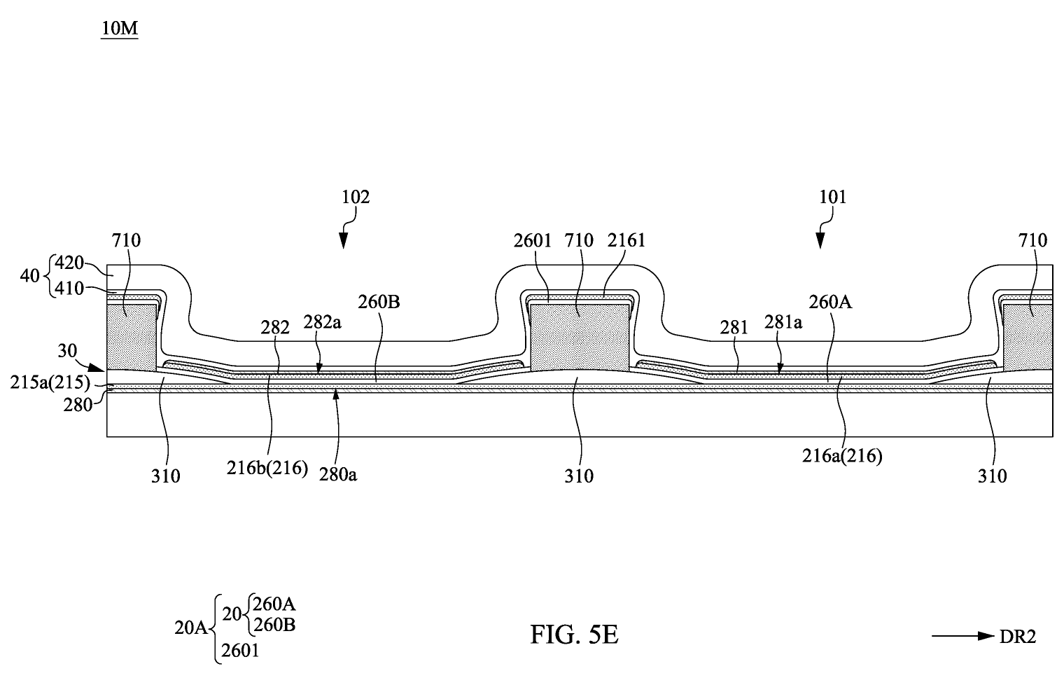

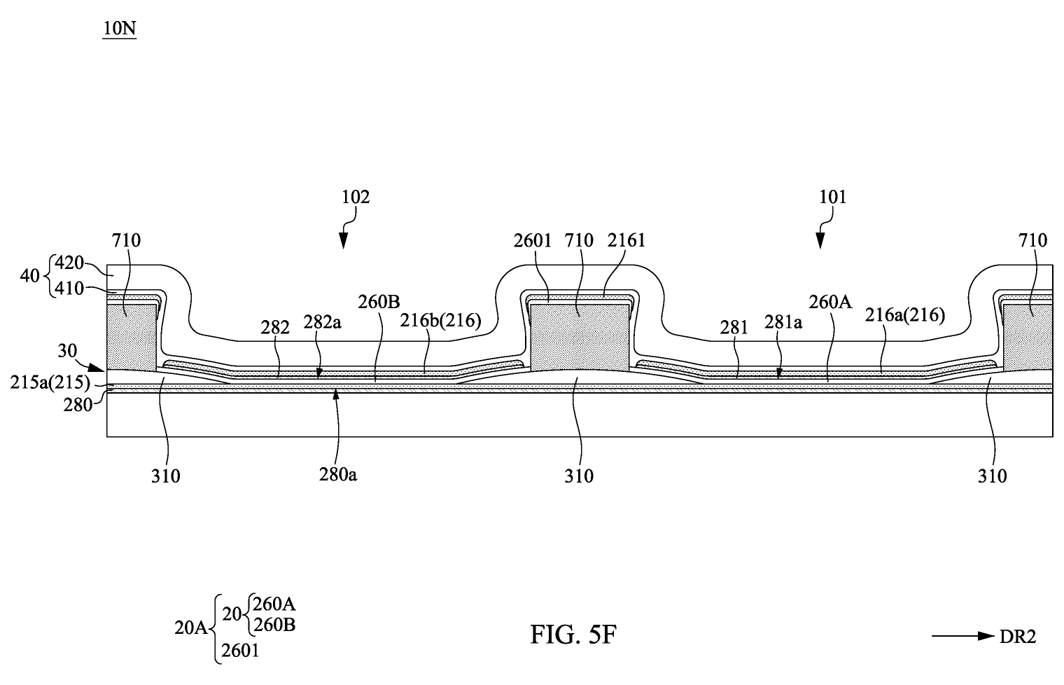

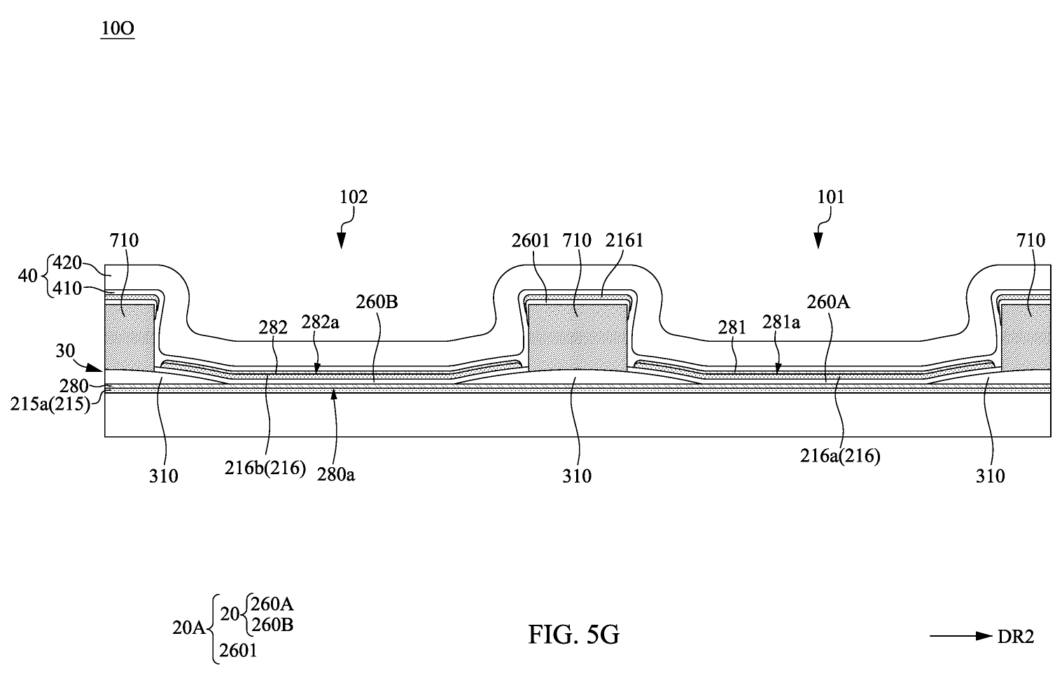

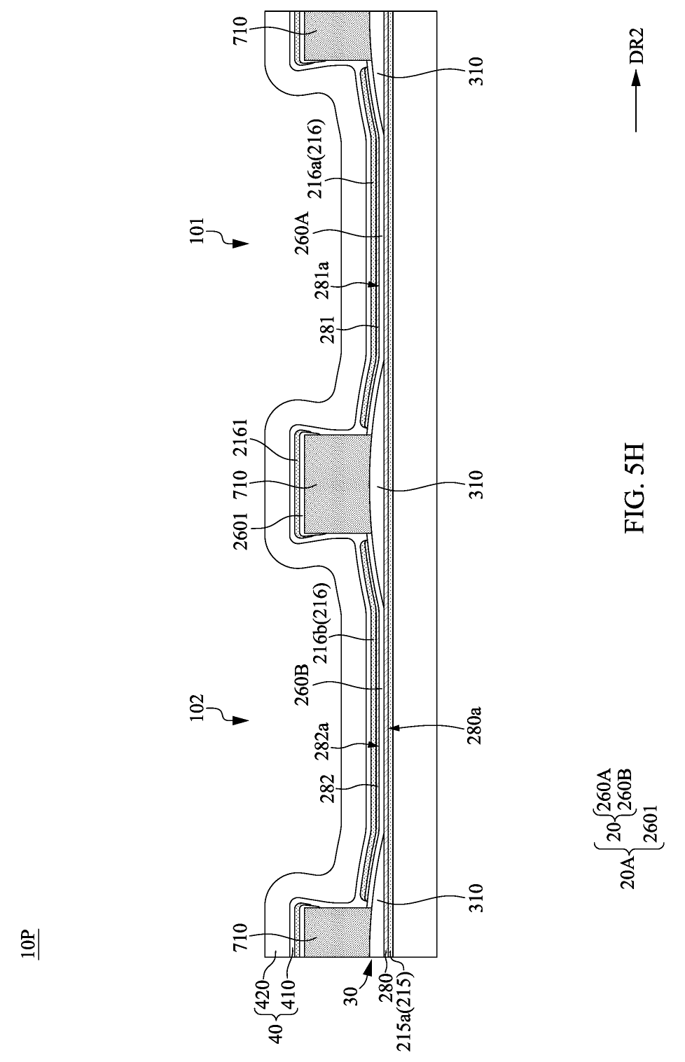

FIG. 5A is a cross-sectional view illustrating an organic light-emitting device 10I. In some embodiments, FIG. 5A is a cross-sectional view illustrating along a line 2A-2A’ in FIG. 4. In some embodiments, FIG. 5A is a cross-sectional view illustrating along the line 2A-2A’ in FIG. 4 and only illustrates the light-emitting region. The spacer structure 30 comprises several bumps 310 to define a light-emitting pixel pattern. A recess is located between two adjacent bumps 310 and provides spaces for accommodating light-emitting pixels. It should be understood by those skilled in the art that when viewed from the cross-sectional view of FIG. 5A, the bumps 310 are shown as disconnected, but when viewed from the top view schematic of FIG. 4, they can be connected to each other via other parts of the spacer structure 30.

As shown in FIG. 5A, in some embodiments, the organic light-emitting device 10I is, for example, a light-emitting device including an organic light-emitting diode (OLED) structure. In some embodiments, the organic light-emitting device 10I includes a plurality of organic light-emitting units (also referred to as light-emitting pixels), for example, including at least an organic light-emitting unit 101 (also referred to as a first organic light-emitting unit) and an organic light-emitting unit 102 (also referred to as a second organic light-emitting unit). In some embodiments, the organic light-emitting units 101 and 102 are located between the bumps 310 and above the substrate 100. The organic light-emitting units 101 and 102 may emit light of the same wavelength or different wavelengths.

In some embodiments, the organic light-emitting device 10I includes a substrate 100, a reflector 280, an electrode 215a (also referred to as a first bottom electrode), an electrode 216a (also referred to as a first top electrode), an electrode 216b (also referred to as a second top electrode), an electrode material layer 2161, an organic light-emitting layer structure 20A (including a light-emitting layer 20 and an organic material layer 2601), the spacer structure 30 (also referred to as a pixel definition layer), and the cover layer 40.

In some embodiments, an organic light-emitting layer structure 20A is located on the electrode 215. In some embodiments, the organic light-emitting layer structure 20A includes the light-emitting layer 20 and an organic material layer 2601. In some embodiments, the light-emitting layer 20 includes an organic light-emitting layer 260A (also referred to as a first organic light-emitting layer) and an organic light-emitting layer 260B (also referred to as a second organic light-emitting layer).

In some embodiments, the electrodes 216a and 216b include conductive materials having high reflectance. In some embodiments, the reflectance of electrodes 216a and 216b for the light emitted from the organic light-emitting layers 260A and 260B is 80% or more, such as 80% or more, 85% or more, 90% or more, or 95% or more.

In some embodiments, the electrode 215a is a transparent electrode and is located above the substrate 100. In some embodiments, the reflector 280 is located between the electrode 215a and the substrate 100, and the reflector 280 includes a surface 280a, which is in contact with the bottom surface of electrode 215a. The arrangement of the reflector 280 can enhance the reflectance of the transparent electrode 215a for the light emitted from the organic light-emitting layers 260A and 260B, providing better resonant cavity effects for each pixel unit. In some embodiments, a reflectance of the arrangement of the reflector 280 for the light emitted from the organic light-emitting layers 260A and 260B is respectively 30% or more (or a transmittance is 70% or less), such as 30% or more, 35% or more, 40% or more, 45% or more, 50% or more, 55% or more, 60% or more, 65% or more, or 70% or more. The higher the reflectance, the better the color purity of the light, and the smaller the light diffusion angle of the organic light-emitting device.

In some embodiments, the reflector 280 includes reflective metal or non-conductive reflective materials. In some embodiments, the reflector 280 includes silver, distributed Bragg reflector (DBR), or other suitable reflective materials. Refer to the above description regarding the examples using DBR as a reflector for further details, which will not be repeated here.

In some embodiments, the spacer structure 30 is located on the substrate 100 and partially covers the electrode 215a. In some embodiments, the spacer structure 30 is located between the organic light-emitting layers 260A and 260B. In some embodiments, the spacer structure 30 is located between the electrode 216a and the electrode 216b. The pattern of the spacer structure 30 may be designed according to pixel arrangement, thus the spacer structure 30 may serve as a pixel definition layer (PDL). In some embodiments, the spacer structure 30 may include bumps 310. The bumps 310 define the pixel area. In some embodiments, the bumps 310 cover parts of the electrode 215a.

In some embodiments, a blocking strip 710 is located on the spacer structure 30 (serving as a pixel definition layer). In some embodiments, the electrode 216a and the electrode 216b are separated by the blocking strip 710, electrically isolated or insulated from each other. The blocking strip 710 may have inclined or vertical sidewalls 710s. In some embodiments, an angle θ between an upper surface 710t and a sidewalls 710s of the blocking strip 710 is between 70° and 110°.

According to some embodiments, material layers formed above the blocking strip 710 and the substrate 100, such as organic light-emitting material layers and electrode material layers, are cut off by the blocking strip 710 to form separate components and material portions remaining on the blocking strip 710. In some embodiments, the organic light-emitting material layer is cut off by the blocking strip 710, forming the organic light-emitting layer 260A and the organic light-emitting layer 260B which are separated from each other and the organic material layer 2601 remaining on the blocking strip 710. In some embodiments, the electrode material layer is cut off by the blocking strip 710, forming the electrode 216a and the electrode 216b which are separated from each other and the electrode material layer 2161 remaining on the blocking strip 710. In some embodiments, the electrode material layer 2161 is located on an upper surface 710t of the blocking strip 710 and extends to the sidewall 710s, and the electrode material layer 2161 is separated from the electrode 216a and the electrode 216b.

In some embodiments, the cover layer 40 includes a capping layer 410 and an encapsulation layer 420. In some embodiments, the capping layer 410 covers the electrode 216a, the electrode 216b, the blocking strip 710, and the organic material layer 2601 and the electrode material layer 2161 remaining on the blocking strip 710. In some embodiments, the encapsulation layer 420 is disposed on the capping layer 410 and is generally conformal with a non-flat upper surface of the capping layer 410.

According to some embodiments shown in FIG. 5A, through the design of disposing a reflector on an outer surface of the transparent electrode 215 (215a), an optical length of the resonant cavity can be further increased. The optical length of the resonant cavity increases by the thickness of the electrode 215 (215a). As such, the optical length of the resonant cavity can be adjusted by adjusting the thickness of the transparent electrode.

FIG. 5B is a cross-sectional view illustrating an organic light-emitting device 10J. The structure of FIG. 5B is similar to that of FIG. 5A, with the difference being that in FIG. 5B, the reflector 280 is disposed on the electrode 215 (215a) and located between the electrode 215 (215a) and the organic light-emitting layers 260A and 260B to provide reflection for light emitted from the organic light-emitting layers 260A and 260B on the side of this electrode (serving as the anode), increasing reflectance to enhance the resonant cavity strength of the organic light-emitting component 10J, so that the purity of the emitted light color can be improved, and the diffusion angle of the emitted light can be reduced. Please refer to the description of FIG. 5A for the other components.

FIG. 5C is a cross-sectional view illustrating an organic light-emitting device 10K. In some embodiments, FIG. 5C illustrates a cross-sectional view of the organic light-emitting device 10’ in FIG. 4. In some embodiments, FIG. 5C illustrates a cross-sectional view along the line 2A-2A’ in FIG. 4. In some embodiments, FIG. 5C illustrates a cross-sectional view along the line 2A-2A’ in FIG. 4 and only illustrates the light-emitting region. The structure of FIG. 5C is similar to that of FIG. 5A, with differences as described below.

In some embodiments, the electrode 216 (216a and 216b) includes conductive materials having high reflectance, such as metal electrodes, and the reflectance of the electrode 216 for light emitted from the organic light-emitting layers 260A and 260B is 80% or more, for example, 80% or more, 85% or more, 90% or more, or 95% or more.

Moreover, in some embodiments, thicknesses of electrodes 216a and 216b are adjusted so that a surface 2162 has a reflectance of at least 80% for light emitted from the organic light-emitting layers 260A and 260B. Moreover, in some embodiments, a thickness Ta of the electrode 216a is the same as a thickness Tb of the electrode 216b. In some embodiments, the thickness Ta of the electrode 216a is different from the thickness Tb of the electrode 216b.

In some embodiments, the electrode 215 (215a) is a transparent electrode, for example, including ITO, IZO, or other suitable materials, and the reflector 280 (providing a surface 280a) is disposed on a surface of the electrode 215 (215a) to increase the reflectance of the light on the side of the electrode 215 (215a), achieving a resonant cavity effect. In some embodiments, as shown in FIG. 5C, the reflector 280 is located between the substrate 100 and the electrode 215a, and the electrode 215a is located between the electrodes 216a, 216b and the light-emitting surface (surface 100b) of the organic light-emitting device 10K. In some embodiments, the reflectance of the reflector 280 for light emitted from the organic light-emitting layers 260A and 260B is 30% or more (e.g., 30% or more, 35% or more, 40% or more, 45% or more, 50% or more, 55% or more, 60% or more, 65% or more, or 70% or more). The higher the reflectance, the better the purity of the light color, and the smaller the light diffusion angle of the organic light-emitting device.

According to some embodiments of the present disclosure, through the design of disposing the reflector (such as the reflector 280 shown in FIG. 5C) on the surface of the transparent electrode (the electrode 215, serving as the anode), the reflectance of the anode can be increased, enhancing the resonant cavity strength of the organic light-emitting device 10K, so that the purity of the emitted light color can be improved, and the diffusion angle of the emitted light can be reduced.

Furthermore, according to some embodiments of the present disclosure, as shown in FIG. 5C, through the design of disposing the reflector on the outer surface of the transparent electrode, the optical length of the resonant cavity can be increased from the distance between the lower surface of the upper electrode and the upper surface of the lower electrode to the distance between the lower surface of the upper electrode and the lower surface of the lower electrode (for example, the lower surface of the transparent electrode 215 and the lower surface of the metal electrodes 216a, 216b in the example shown in FIG. 5C), or to the distance between the interior of the reflector 280 and the lower surface of the upper electrode (depending on the material of the reflector); that is, the optical length of the resonant cavity is increased by at least the thickness of the lower electrode (e.g., the transparent electrode 215). As such, the optical length of the resonant cavity can be adjusted by adjusting the thickness of the transparent electrode.

Additionally, when the organic light-emitting layers 260A and 260B emit light of different colors, the optimal optical lengths of the resonant cavities of their pixel units differ. According to some embodiments of the present disclosure, the thickness of electrodes 216a, 216b (such as metal electrodes in the example shown in FIG. 5C) or the thickness or material of the reflector may be adjusted to adjust the electrode reflectance, or the thickness of the transparent electrode may be adjusted to modify the optical length of the resonant cavity, or both may be adjusted and matched simultaneously to provide the optimal resonant cavity effect for the pixel units of each color, thereby improving the optical performance of the organic light-emitting device 10K.

FIG. 5D is a cross-sectional view illustrating an organic light-emitting device 10L. The structure of FIG. 5D is similar to that of FIG. 5C, with the difference being that in FIG. 5D, the reflector 280 is disposed between the electrode 215 (215a) and the organic light-emitting layers 260A and 260B to provide reflection for the light emitted from the organic light-emitting layers on the side of this electrode (serving as the anode), increasing reflectance to enhance the resonant cavity strength of the organic light-emitting component 10L, so that the purity of the emitted light color can be improved, and the diffusion angle of the emitted light can be reduced. Please refer to the description of FIG. 5C for the other components.

FIG. 5E is a cross-sectional view illustrating an organic light-emitting device 10M. In some embodiments, FIG. 5E illustrates a cross-sectional view of the organic light-emitting device 10’ in FIG. 4. In some embodiments, FIG. 5E illustrates a cross-sectional view along the line 2A-2A’ in FIG. 4. In some embodiments, FIG. 5E illustrates a cross-sectional view along the line 2A-2A’ in FIG. 4 and only illustrates the light-emitting region. The structure of FIG. 5E is similar to that of FIG. 5A, with differences described as follows.

In some embodiments, the electrode 215 (215a) is a transparent electrode located above the substrate 100. In some embodiments, the electrodes 216a and 216b are transparent electrodes, and are located above the organic light-emitting layers 260A and 260B, respectively. In some embodiments, a blocking strip 710 is located on the bump 310 (or the spacer structure 300), and the electrodes 216a and 216b are separated by the blocking strip 710, electrically isolated or insulated from each other. In some embodiments, reflectors are placed on outer surfaces of the electrodes 215, 216a, and 216b to increase the reflectance of the transparent electrodes.

Specifically, in some embodiments, as shown in FIG. 5E, the reflector 280 is disposed on the electrode 215 (215a) and located between the electrode 215 (215a) and the substrate 100, with a surface 280a of the reflector 280 in contact with the electrode 215 (215a). In some embodiments, the reflectors 281 and 282 are located on the electrodes 216a and 216b, respectively, with surfaces 281a and 282a in contact with the electrodes.

In some embodiments, the reflectors 280, 281, and 282 are disposed to reflect light emitted from the organic light-emitting layers 260A and 260B. In some embodiments, the reflectors 281 and 282 are disposed to have a reflectivity of 30% or more (e.g., 30% or more, 35% or more, 40% or more, 45% or more, 50% or more, 55% or more, 60% or more, 65% or more, or 70% or more) for light emitted from the organic light-emitting layers 260A and 260B, the reflector 280 is disposed to have a reflectivity of 80% or more (e.g., 80% or more, 85% or more, 90% or more, or 95% or more) for light emitted from the organic light-emitting layers 260A and 260B, and the organic light-emitting device 10M emits light toward the encapsulation layer 420.

In some other embodiments, the reflectors 281 and 282 are disposed to have a reflectivity of 80% or more (e.g., 80% or more, 85% or more, 90% or more, or 95% or more) for light emitted from the organic light-emitting layers 260A and 260B, the reflector 280 is disposed to have a reflectivity of 30% or more (e.g., 30% or more, 35% or more, 40% or more, 45% or more, 50% or more, 55% or more, 60% or more, 65% or more, or 70% or more) for the light emitted from the organic light-emitting layers 260A and 260B, and the organic light-emitting device 10M emits light toward the substrate 100.

In some embodiments, the reflectors 280, 281, and 282 include reflective metal or non-conductive reflective materials. In some embodiments, the reflectors 280, 281, and 282 include silver, distributed Bragg reflectors (DBR), or other suitable reflective materials. Refer to the above description regarding the use of DBR as an example of one of the reflectors, which will not be repeated here.

Moreover, in some embodiments, in different pixel units, the reflectance provided by the reflector 282 may be the same as or different from the reflectance provided by the reflector 281. In some embodiments, the thickness of the reflector 281 may be the same as or different from the thickness of the reflector 282.

In some embodiments, after forming the reflectors 281 and 282, the blocking strip 710 may be left or removed. In some embodiments, a capping layer 410 covers the reflectors 281, 282, the electrode 216a, the electrode 216b, the blocking strip 710 (if left), and the organic material layer 2601 and the electrode material layer 2161 remaining on the blocking strip 710. In some embodiments, an encapsulation layer 420 is disposed on the capping layer 410 and is generally conformal with the non-flat upper surface of the capping layer 410. The capping layer 410 and the encapsulation layer 420 form the cover layer 40.

According to some embodiments of the present disclosure, as shown in FIG. 5E, through the design of disposing reflectors on both sides of the transparent anode and transparent cathode, the reflectance of the anode and cathode can be increased, enhancing the resonant cavity strength of the organic light-emitting device 10M, so that the purity of the emitted light color can be improved and the diffusion angle of the emitted light can be reduced.

Moreover, according to some embodiments of the present disclosure, as shown in FIG. 5E, through the design of disposing reflectors on both sides of the transparent anode and transparent cathode, the optical length of the resonant cavity can be further increased, such that the optical length of the resonant cavity is increased by at least the thickness of the upper electrode (e.g., the electrodes 216a, 216b) and the thickness of the lower electrode (e.g., the electrode 215a). As such, the optical length of the resonant cavity can be adjusted by adjusting the thickness of the transparent electrodes.

FIG. 5F is a cross-sectional view illustrating an organic light-emitting component 10N. The structure of FIG. 5F is similar to that of FIG. 5E, with the difference being that in FIG. 5F, the reflectors 281 and 282 are respectively disposed below the electrodes 216a and 216b, and are located between the electrodes and the organic light-emitting layer. Specifically, as shown in FIG. 5F, the reflector 281 is disposed between the electrode 216a and the organic light-emitting layer 260A, and the reflector 282 is disposed between the electrode 216b and the organic light-emitting layer 260B. In this way, the reflectance of the anode and cathode can be increased, enhancing the cavity strength of the organic light-emitting device 10N, so that the purity of the emitted light color can be improved, and the diffusion angle of the emitted light can be reduced. Please refer to the description in FIG. 5E for the other components.

FIG. 5G is a cross-sectional view illustrating an organic light-emitting component 10O. The structure of FIG. 5G is similar to that of FIG. 5E, with the difference being that in FIG. 5G, the reflector 280 is disposed on the electrode 215 (215a) and is located between the electrode 215 (215a) and the organic light-emitting layers 260A and 260B. The reflectors 281 and 282 in FIG. 5G are the same as those in FIG. 5E, respectively located on the electrodes 216a and 216b so as to increase the reflectance of the anode and cathode, enhancing the cavity strength of the organic light-emitting device 10O, so that the purity of the emitted light color can be improved, and the diffusion angle of the emitted light can be reduced. Please refer to the description in FIG. 5E for the other components.

FIG. 5H is a cross-sectional view illustrating an organic light-emitting component 10P. The structure of FIG. 5H is similar to that of FIG. 5E, with the difference being that the reflectors on both sides are disposed between the electrodes and the organic light-emitting layer (i.e., on an inner surface of the electrodes). Specifically, as shown in FIG. 5H, the reflectors 281 and 282 are respectively disposed on the electrodes 216a and 216b, and the reflector 280 is disposed between the electrode 215 and the organic light-emitting layers 260A and 260B, and in this way the reflectance of the anode and cathode can be increased, enhancing the cavity strength of the organic light-emitting component 10P, so that the purity of the emitted light color can be improved, and the diffusion angle of the emitted light can be reduced. Please refer to the description in FIG. 5E for the other components.

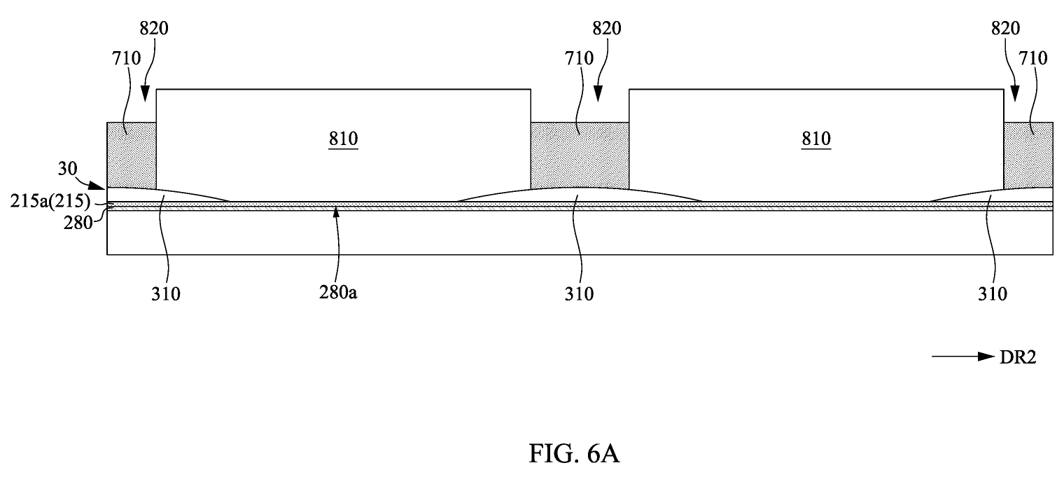

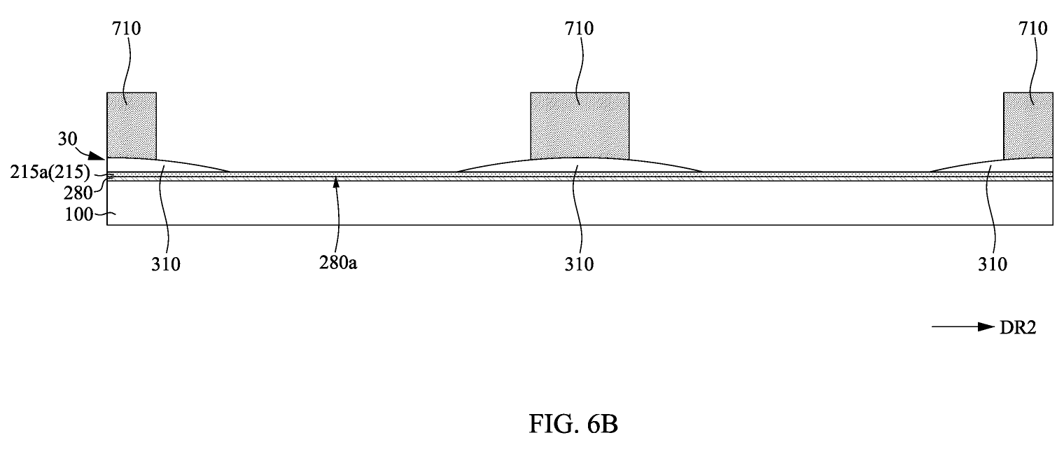

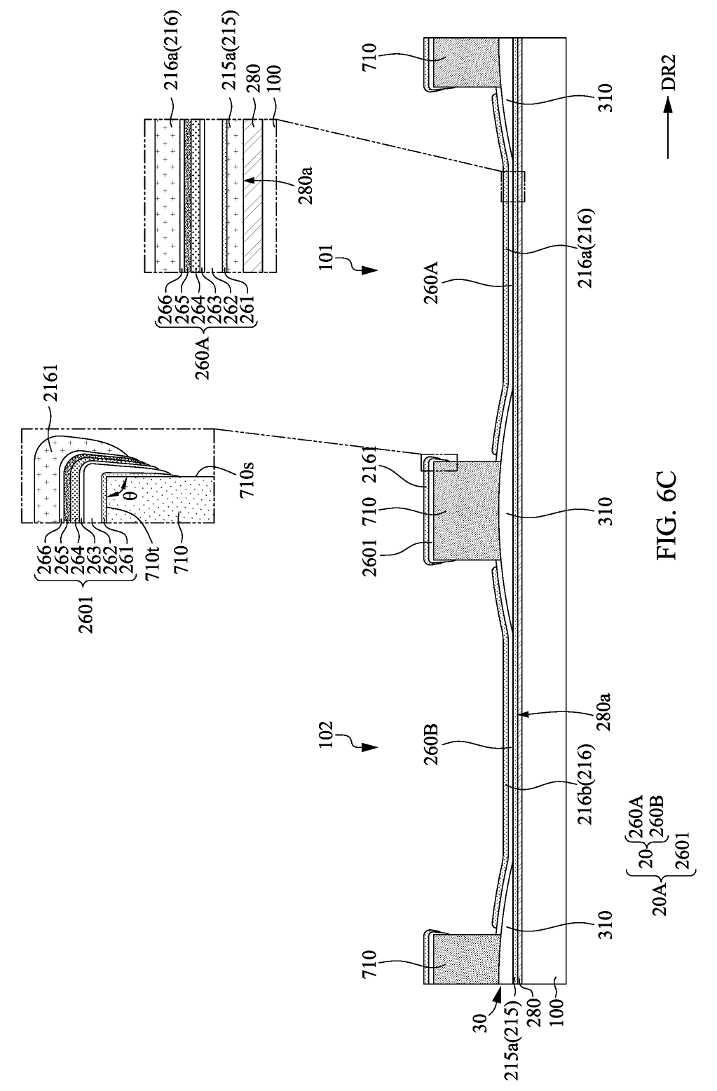

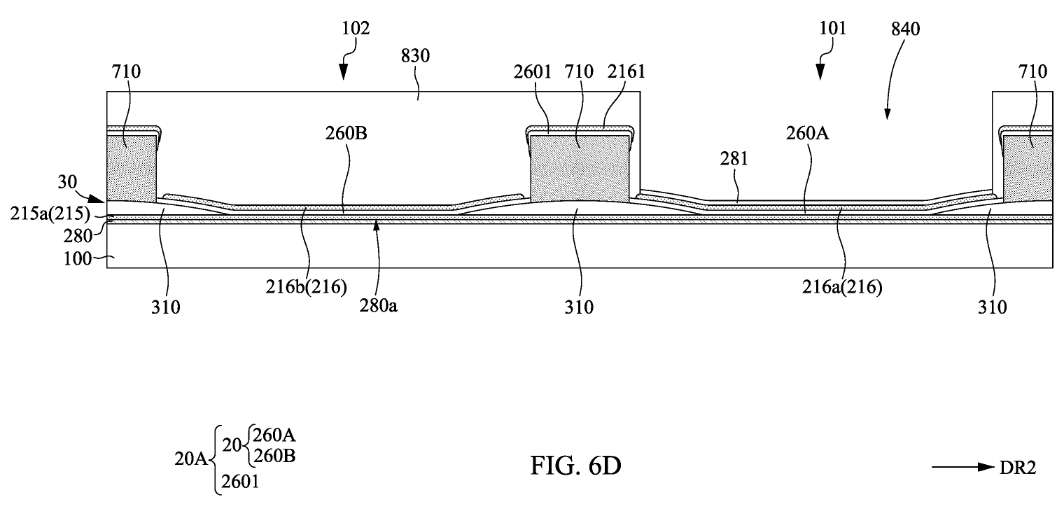

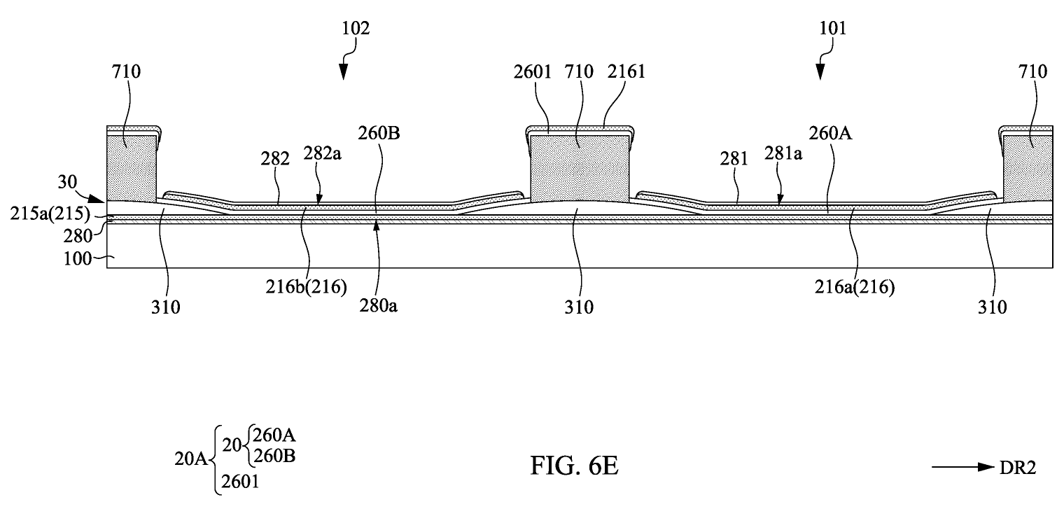

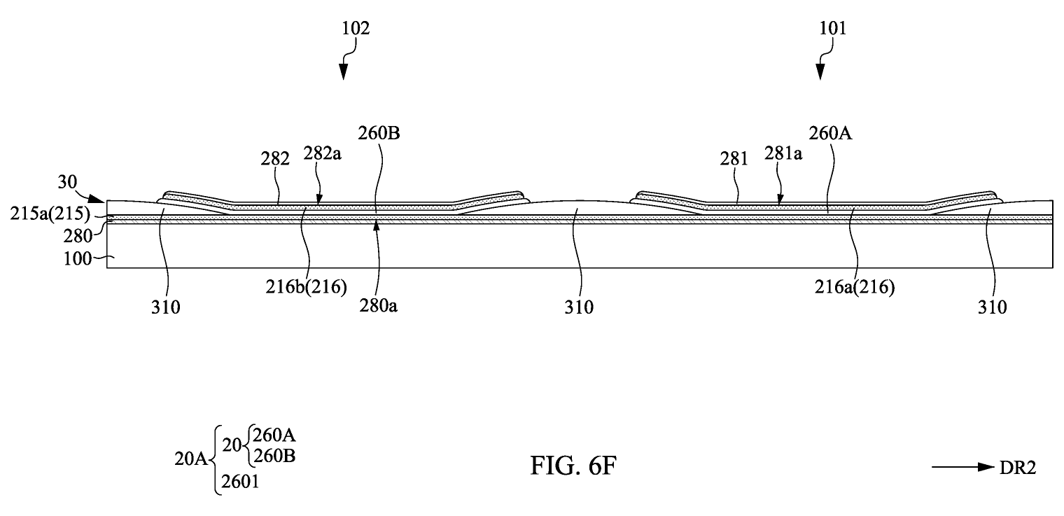

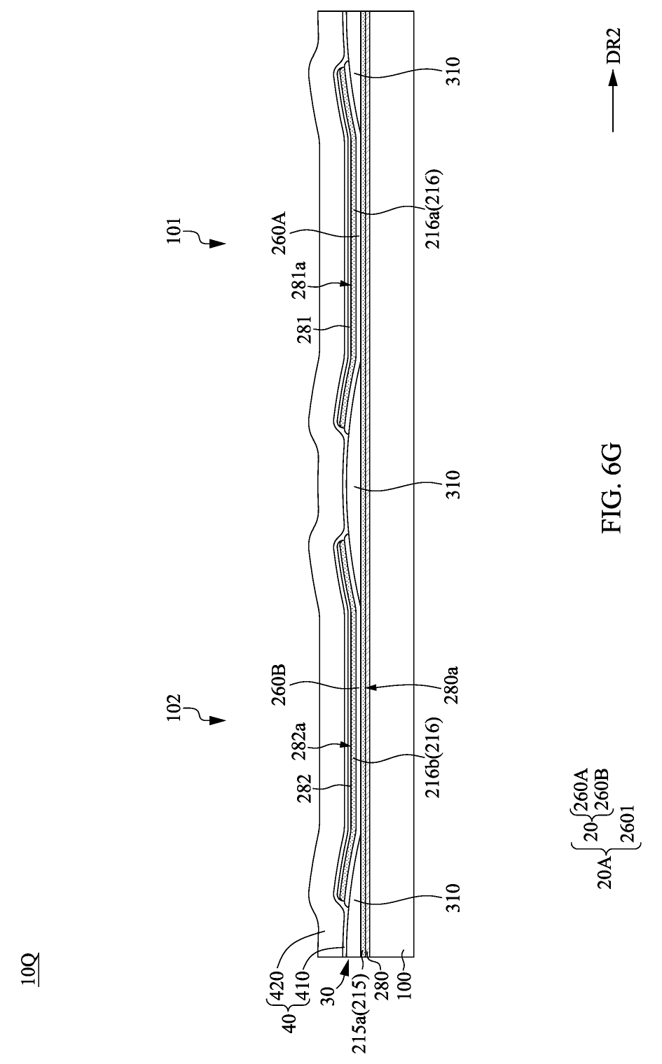

FIGS. 6A to 6G illustrate a manufacturing method of an organic light-emitting device 10Q according to some embodiments. The structure of FIG. 6G is similar to that of FIG. 5E, with the difference being the removal of the blocking strip 710 from FIG. 5E.

As shown in FIG. 6A, in some embodiments, a substrate 100 is provided, and a reflector 280 and an electrode 215a are disposed on the substrate 100, and a plurality of bumps 310 (or spacer structures 30) are formed on the electrode 215a. In some embodiments, a plurality of electrodes 215 are disposed on the substrate 100 (refer to FIG. 4), and the spacer structure 30 is formed on the plurality of electrodes 215. The plurality of electrodes 215 may be manufactured through a photolithography etching process. Next, in some embodiments, a photosensitive layer 810 is disposed on the spacer structure 30 and the electrode 215a. In some embodiments, a photosensitive material is formed through coating, and then patterned through a photolithography process to form the photosensitive layer 810, so as to expose part of the bump 310 through a recess 820. Next, a blocking strip 710 is formed in the recess 820. The blocking strip 710 may be formed by coating and etching back the blocking material.

As shown in FIG. 6B, in some embodiments, the photosensitive layer 810 is removed, for example, through a wet etching process.

As shown in FIG. 6C, in some embodiments, an organic light-emitting layer structure 20A and an electrode material layer are formed on the spacer structure 30, the electrode 215a, and the blocking strip 710.

In some embodiments, an organic light-emitting material layer is formed above the blocking strip 710 and the substrate 100, so that the organic light-emitting material layer is cut by the blocking strip 710 to form an organic light-emitting layer 260A and an organic light-emitting layer 260B which are separated from each other. In some embodiments, a complete organic light-emitting material layer is formed through evaporation on the spacer structure 30, the electrode 215a, and the blocking strip 710, with the complete organic light-emitting material layer being cut by the blocking strip 710 to form the organic light-emitting layer 260A and the organic light-emitting layer 260B which are separated from each other, and the organic material layer 2601 remaining on the blocking strip 710 and partially extending to a sidewall 710s.

In some embodiments, a hole injection layer (HIL) 261, a hole transport layer (HTL) 262, an electron blocking layer (EBL) 263, an organic emission layer (EM) 264, an electron transport layer (ETL) 265, and an electron injection layer (EIL) 266 are sequentially formed through evaporation on surfaces of the spacer structure 30, the electrode 215a, and the blocking strip 710.

In some embodiments, a complete electrode material layer is formed through evaporation on the spacer structure 30, the electrode 215a, and the blocking structure 70, so that the complete electrode material layer is cut by the blocking strip 710 to form an electrode 216a and an electrode 216b which are separated from each other, and the electrode material layer 2161 remaining on the blocking strip 710 and partially extending to the sidewall 710s.

As shown in FIG. 6D, in some embodiments, a photosensitive layer 830 is disposed above the substrate 100, and the photosensitive layer 830 includes an opening 840 to expose the electrode 216a. A photosensitive material may be formed through coating. Next, in some embodiments, the photosensitive material is patterned through a photolithography process to form the photosensitive layer 830, exposing part of the electrode 216a through the opening 840. Next, in some embodiments, a reflector 281 is formed in the opening 840. In some embodiments, one or more pairs of DBRs are formed as the reflector 281 by alternately stacking dielectric material layers with high and low refractive indices. Afterward, the photosensitive layer 830 is removed. In some embodiments, the photosensitive layer 830 is removed through a wet etching process.

As shown in FIG. 6E, the steps described in FIG. 6D are repeated to form a reflector 281 on the electrode 216a and a reflector 282 on the electrode 216b.

As shown in FIG. 6F, in some embodiments, the blocking strip 710 is removed to form a recess S2 defined by local upper surfaces of the electrode 216a, the electrode 216b, the reflector 281, the reflector 282, and the bump 310 (or pixel definition layer). In some embodiments, the blocking strip 710 is removed through a lift-off process.

As shown in FIG. 6G, in some embodiments, a capping layer 410 is disposed (e.g., through deposition) on the electrode 216a and the electrode 216b and covering the reflector 281 and the reflector 282. Subsequently, in some embodiments, an encapsulation layer 420 is disposed on the capping layer 410. At this point, the organic light-emitting device 10Q shown in FIG. 6G is formed.

The features of some embodiments are given in brief in the description above for a person skilled in the art to better understand various aspects of the present disclosure. A person skilled in the art would able to understand that the present disclosure can be used as the basis for designing or modifying other manufacturing processes and structures so as to achieve the same objects and/or the same advantages of the embodiments described in the present application. A person skilled in the art would also be able to understand that such structures do not depart from the spirit and scope of the disclosure of the present application, and various changes, substitutions and replacements may be made by a person skilled in the art without departing from the spirit and scope of the present disclosure.

What is claimed is:

1. An organic light-emitting device, comprising:
a substrate;
a first electrode located on the substrate;
an organic light-emitting layer located on the first electrode; and
a second electrode located on the organic light-emitting layer, one of the first electrode and the second electrode comprising a transparent electrode,
wherein one of the first electrode and the second electrode provides a reflectance of 30% or more for light emitted from the organic light-emitting layer, while the other provides a reflectance of 80% or more for the light emitted from the organic light-emitting layer.

2. The organic light-emitting device of claim 1, wherein the first electrode is the transparent electrode, and the organic light-emitting device further comprises:
a first reflector located on the transparent electrode, and the first reflector located between the substrate and the transparent electrode, or the first reflector located between the transparent electrode and the organic light-emitting layer, wherein the first reflector is disposed to provide a reflection for the light emitted from the organic light-emitting layer.

3. The organic light-emitting device of claim 2, wherein the second electrode comprises another transparent electrode, and the organic light-emitting device further comprises:
a second reflector located on the second electrode, and the second electrode located between the second reflector and the organic light-emitting layer, or the second reflector located between the second electrode and the organic light-emitting layer,
wherein a reflectance provided by the first reflector when disposed to reflect the light emitted from the organic light-emitting layer is different from a reflectance provided by the second reflector when disposed to reflect the light emitted from the organic light-emitting layer.

4. The organic light-emitting device of claim 3, wherein a thickness of the first reflector is different from a thickness of the second reflector.

5. The organic light-emitting device of claim 3, wherein the organic light-emitting layer is a first organic light-emitting layer, and the organic light-emitting device further comprises:
a third electrode located on the substrate, wherein the third electrode and the first electrode include a same transparent conductive material;
a second organic light-emitting layer located on the third electrode;
a third reflector located on the third electrode, and the third reflector located between the substrate and the third electrode, or the third reflector located between the third electrode and the second organic light-emitting layer;
a fourth electrode, including a same transparent conductive material as the second electrode, located on the second organic light-emitting layer; and
a fourth reflector located on the fourth electrode, and the fourth electrode located between the fourth reflector and the second organic light-emitting layer, or the fourth reflector located between the fourth electrode and the second organic light-emitting layer, wherein a reflectance provided by the fourth reflector when disposed to reflect light emitted from the second organic light-emitting layer is different from a reflectance provided by the third reflector when disposed to reflect the light emitted from the second organic light-emitting layer.

6. The organic light-emitting device of claim 5, wherein a thickness of the first electrode is different from a thickness of the third electrode.

7. The organic light-emitting device of claim 5, wherein a thickness of the second reflector is different from a thickness of the fourth reflector.

8. The organic light-emitting device of claim 1, wherein the first electrode is a first metal electrode, the organic light-emitting layer is a first organic light-emitting layer, the second electrode is the transparent electrode, and the organic light-emitting device further comprises:
a first reflector located on the second electrode, and the second electrode located between the first reflector and the first organic light-emitting layer, or the first reflector located between the second electrode and the first organic light-emitting layer;
a third electrode located on the substrate, wherein the third electrode is a second metal electrode;
a second organic light-emitting layer located on the third electrode;
a fourth electrode, which is another transparent electrode, located on the second organic light-emitting layer; and
a second reflector located on the fourth electrode, and the fourth electrode located between the second reflector and the second organic light-emitting layer, or the second reflector located between the fourth electrode and the second organic light-emitting layer.

9. The organic light-emitting device of claim 8, wherein a reflectance provided by the first reflector when disposed to reflect light emitted from the first organic light-emitting layer is different from a reflectance provided by the second reflector when disposed to reflect light emitted from the second organic light-emitting layer.

10. The organic light-emitting device of claim 1, wherein the first electrode is the transparent electrode, the second electrode is a first metal electrode, the organic light-emitting layer is a first organic light-emitting layer, and the organic light-emitting device further comprises:
a reflector located between the first electrode and the substrate, or between the first electrode and the first organic light-emitting layer;
a third electrode, which is another transparent electrode, located on the substrate;
a second organic light-emitting layer located on the third electrode, wherein the reflector extends between the third electrode and the substrate, or extends between the third electrode and the second organic light-emitting layer; and
a fourth electrode located on the second organic light-emitting layer, the fourth electrode being a second metal electrode,
wherein a reflectance provided by the reflector when disposed to reflect light emitted from the second organic light-emitting layer is different from a reflectance provided by the reflector when disposed to reflect light emitted from the first organic light-emitting layer.

11. The organic light-emitting device of claim 10, wherein a thickness of the second electrode is different from a thickness of the fourth electrode.

12. A manufacturing method of an organic light-emitting device, comprising:
providing a substrate;
disposing a first electrode on the substrate;
forming an organic light-emitting layer on the first electrode; and
disposing a second electrode on the organic light-emitting layer, one of the first electrode and the second electrode comprising a transparent electrode,
wherein a reflectance provided by one of the first electrode and the second electrode when disposed to reflect light emitted from the organic light-emitting layer is 30% or more, and a reflectance provided by the other of the first electrode and the second electrode when disposed to reflect the light emitted from the organic light-emitting layer is 80% or more.

13. The manufacturing method of claim 12, further comprising:
using a transparent conductive material to form the first electrode; and
disposing a first reflector on a surface of the first electrode,
wherein the first reflector is located between the substrate and the first electrode, or the first reflector is located between the first electrode and the organic light-emitting layer.

14. The manufacturing method of claim 13, wherein another transparent conductive material is used to form the second electrode, and the manufacturing method further comprises:
disposing a second reflector on the second electrode, and the second electrode located between the second reflector and the organic light-emitting layer, or the second reflector located between the second electrode and the organic light-emitting layer,
wherein a reflectance provided by the first reflector when disposed to reflect the light emitted from the organic light-emitting layer is different from a reflectance provided by the second reflector when disposed to reflect the light emitted from the organic light-emitting layer.

15. The manufacturing method of claim 14, further comprising:
using the transparent conductive material to form a third electrode on the substrate, wherein the third electrode and the first electrode are disposed to be separated from each other;
disposing a third reflector on a surface of the third electrode;
forming a second organic light-emitting layer on the third electrode, wherein the third reflector is located between the substrate and the third electrode, or the third reflector is located between the third electrode and the second organic light-emitting layer;
forming a fourth electrode on the second organic light-emitting layer; and
forming a fourth reflector on the fourth electrode, and the fourth electrode located between the fourth reflector and the second organic light-emitting layer, or the fourth reflector located between the fourth electrode and the second organic light-emitting layer,
wherein a reflectance provided by the fourth reflector when disposed to reflect light emitted from the second organic light-emitting layer is different from a reflectance provided by the second reflector when disposed to reflect the light emitted from the second organic light-emitting layer.

16. The manufacturing method of claim 15, wherein a thickness of the fourth electrode is different from a thickness of the second electrode.

17. The manufacturing method of claim 12, comprising:
using a transparent conductive material to make one of the first electrode and the second electrode, so that a reflectance of the one of the first electrode and the second electrode to the light emitted from the organic light-emitting layer is 30% or more;
using a metal material to make the other of the first electrode and the second electrode, so that a reflectance of the other of the first electrode and the second electrode to the light emitted from the organic light-emitting layer is 80% or more; and
disposing a reflector on one of the first electrode and the second electrode made of the transparent conductive material, so that a reflectance provided by the reflector when disposed to reflect the light emitted from the organic light-emitting layer is 30% or more.
